(19) United States
(12) Patent Application Publication
(10) Pub. No.: US 2024/0072826 A1
(43) Pub. Date: Feb. 29, 2024

(54) Adaptive Low-Density Parity Check Decoder

(71) Applicant: Marvell Asia Pte Ltd, Singapore (SG)

(72) Inventors: Xuanxuan Lu, San Jose, CA (US); Nedeljko Varnica, San Jose, CA (US)

(73) Assignee: Marvell Asia Pte Ltd, Singapore (SG)

(21) Appl. No.: 18/452,316

(22) Filed: Aug. 18, 2023

Related U.S. Application Data
(60) Provisional application No. 63/400,062, filed on Aug. 23, 2022.

(51) Int. Cl. H03M 13/11; H03M 13/00

(52) U.S. Cl. CPC H03M 13/1111; H03M 13/1108; H03M 13/6318

(57) ABSTRACT

The present disclosure describes apparatuses and methods for implementing an adaptive low-density parity check (LDPC) decoder. In various aspects, an adaptive LDPC decoder processes a first portion of data using first parameters effective to change a status of the LDPC decoder. The LDPC decoder selects second parameters of the LDPC decoder based on the status of the LDPC decoder. The LDPC decoder then processes a second portion of the data with the LDPC decoder using the second parameters and provides decoded data of the channel based on at least the processing the first portion of the data using the first parameters and the processing of the second portion of the data using the second parameters. By adaptively altering the decoding parameters based the status of the decoder, the adaptive LDPC decoder may decode channel data in fewer decoding iterations or with a higher success rate, thereby improving LDPC decoding performance.

### CROSS REFERENCE TO RELATED APPLICATION

This present disclosure claims priority to U.S. Provisional Patent Application Ser. No. 63/400,062 filed Aug. 23, 2022, the disclosure of which is incorporated by reference herein in its entirety.

### BACKGROUND

Many computing and electronic devices transfer data to provide various functions of a device. Data transfer systems, such as data transmission systems and data storage systems, are typically characterized as data channels. In data transmission systems, for example, data can be transmitted via channels such as printed circuit board (PCB) traces, wire cables, fiber-optic cables, wireless protocols, and so forth. In a data storage system, a storage medium to which data is written and from which data is read may be considered a data channel of the data storage system. Thus, a data storage data channel may include magnetic storage media, optical storage media, holographic storage media, solid-state storage media, or the like.

An efficiency and reliability of a data channel can depend on many factors, such as a signal-to-noise ratio (SNR) of the channel. For example, storage media having a high SNR generally enables more accurate storage and recovery of data. On the other hand, storage media having a low SNR can result in high rates of data errors, such as misread or unrecoverable data. Similarly, quality of a digital data communication channel depends on an SNR of the channel, where a high-SNR communication channel can communicate data quickly and accurately and a low-SNR communication channel may have difficulty conveying data through the channel (e.g., dropped data packets).

Error correcting code (ECC) can provide a way to reduce errors in data storage and transmission by introducing data redundancy into a communication channel, typically in the form of extra bits that enable checking of the validity of original data. ECCs utilize codewords, which are specific patterns of bits or symbols in a storage medium or transmission signal, to group data into chunks to be checked for errors. Most ECCs, however, are implemented with a static configuration that may be sub-optimal or unable to account for any variation in the data or the channel by which the data is transferred. This can result in excessive ECC-related processing of data or a failure to complete decoding of the data. As such, communication systems or storage systems with static ECC configurations may be inefficient, reduce data throughput, suffer data loss, or consume excess power.

### SUMMARY

This summary is provided to introduce subject matter that is further described in the Detailed Description and Drawings. Accordingly, this Summary should not be considered to describe essential features or used to limit the scope of the claimed subject matter.

In some aspects, a method for adaptive low-density parity check (LDPC) decoding comprises processing a first portion of data of a channel with an LDPC decoder using first parameters effective to change a status of the LDPC decoder. The method selects second parameters of the LDPC decoder based on the status of the LDPC decoder and processes a second portion of the data with the LDPC decoder using the second parameters (e.g., during a same or single iteration). The method then provides decoded data of the channel based on at least the processing the first portion of the data with the first parameters and the processing of the second portion of the data with the second parameters. In aspects, the adaptive decoder may determine multiple portions or subsets of data from the received data and process each of the multiple portions using adaptively selected or determined decoding parameters. By adaptively altering the decoding parameters based the status of the decoder, the adaptive LDPC decoder may decode channel data in fewer decoding iterations or with a higher success rate, thereby improving LDPC decoding performance.

In other aspects, an apparatus comprises a data interface configured for communication of data through a channel, an LDPC decoder, and an adaptive controller for the LDPC decoder. The adaptive controller is configured to process, with the LDPC decoder and using first parameters, a first block of data received from the channel effective to change metrics of the LDPC decoder. The controller selects second parameters for the LDPC decoder based on the metrics of the LDPC decoder and processes, with the LDPC decoder and using the second parameters, a second block of the data. The adaptive controller provides, from the LDPC decoder, decoded data of the channel based on at least the processing of the first block using the first parameters and the processing of the second block using the second parameters.

In yet other aspects, a System-on-Chip (SoC) is described that includes a media interface to access storage media of a storage system, a host interface to communicate with a host system, an LDPC decoder, and an adaptive controller for the LDPC decoder. The adaptive controller is configured to process, with the LDPC decoder and using first parameters, a first block of data received from the channel effective to change a status of the LDPC decoder. The controller selects second parameters for the LDPC decoder based on the status of the LDPC decoder and processes, with the LDPC decoder and using the second parameters, a second block of the data. The adaptive controller then provides, from the LDPC decoder, decoded data of the channel based on at least the processing of the first block of data using the first parameters and the processing of the second block of data using the second parameters.

The details of one or more implementations are set forth in the accompanying drawings and the following description. Other features and advantages will be apparent from the description and drawings and from the claims.

### BRIEF DESCRIPTION OF THE DRAWINGS

The details of one or more implementations of an adaptive low-density parity check (LDPC) decoder are set forth in the accompanying figures and the detailed description below. In the figures, the left-most digit of a reference number identifies the figure in which the reference number first appears. The use of the same reference numbers in different instances in the description and the figures indicates like elements:

FIG. 1 illustrates an example operating environment having systems in which an adaptive LDPC decoder is implemented in accordance with one or more aspects of the disclosure;

FIG. 2 illustrates an example of a data channel in which a decoder may implement aspects of adaptive LDPC decoding;

FIG. 3 illustrates an example configuration of a storage system that includes an adaptive LDPC decoder implemented in accordance with one or more aspects;

FIG. 4 illustrates example Tanner graphs of LDPC data that may be processed with an adaptive LDPC decoder;

FIG. 5 illustrates an example algorithm that an adaptive LDPC decoder may implement in accordance with various aspects;

FIG. 6 illustrates an example algorithm for adaptive LDPC decoding with thresholds adjusted based on a syndrome of the LDPC decoder;

FIG. 7 depicts an example method for adaptive LDPC decoding in accordance with one or more aspects;

FIG. 8 depicts an example method for implementing adaptive LDPC decoding based on a syndrome of a decoder;

FIGS. 9A and 9B depict an example method for selecting decoding parameters of an adaptive LDPC decoder based on a status of the decoder;

FIG. 10 depicts an example method for selecting parameters of an adaptive LDPC decoder based on results of processing data with combinations of parameters;

FIG. 11 illustrates an example System-on-Chip (SoC) environment in which aspects of adaptive LDPC decoding may be implemented; and

FIG. 12 illustrates an example storage system controller in which an adaptive LDPC decoder is implemented in accordance with one or more aspects.

### DETAILED DESCRIPTION

Many computing and electronic devices transfer data to provide various functions of a device. Data transfer systems, such as data transmission systems and data storage systems, are typically characterized as data channels. Generally, error correcting code (ECC) can provide a way to reduce errors in data storage and transmission by introducing data redundancy into a communication channel, typically in the form of extra bits that enable checking of the validity of original data. ECCs utilize codewords, which are specific patterns of bits or symbols in a storage medium or transmission signal, to group data into chunks to be checked for errors. Most ECCs, however, are implemented with a static configuration (e.g., pre-set static rules) that may be sub-optimal or unable to account for any variation in the data or the channel by which the data is transferred, which may result in excessive ECC-related processing of data. As such, communication systems or storage systems with static ECC configurations may be inefficient, reduce data throughput, suffer data loss, or consume excess power.

This disclosure describes apparatuses and techniques for adaptive low-density parity check (LDPC) decoding. In contrast with preceding ECC techniques, the described apparatuses and techniques may implement an adaptive LDPC decoder that changes or selects decoding rules (e.g., thresholds) dynamically based on a status of the decoder enabling the decoder to adapt on-the-fly during the decoding process. By so doing, an adaptive LDPC decoder can achieve faster convergence in a bit-flipping decoder, improve decoder throughput, reduce decoder latency, or reduce an average number of processing iterations taken to decode data. Generally, the described aspects may implement an adaptive decoding process in which a bit-flipping or symbol-flipping decoder can employ dynamic flipping rules within an iteration of the decoding process. In some implementations of adaptive decoding, the decoding rules (e.g., flipping thresholds) change adaptively based on the status (e.g., metrics) of the decoder at each point in the decoding (e.g. real-time status within each decoding iteration) instead of the decoder using fixed rules values throughout a given iteration for all bits in the LDPC code of the data being decoded.

In various aspects, the status of the decoder may include one or more of a syndrome weight, a column weight, a LDPC code being decoded, an iteration index, a block index, whether a bit (or symbol) flipped or not flipped (e.g., flip status), and so on. Thus, in addition to an iteration number or a flip status of a bit, an adaptive controller of the LDPC decoder may set or select decoding rules (e.g., the flipping thresholds) based on a real-time status of the decoder. In some aspects, the adaptive controller uses a sum of syndrome values (current syndrome weight) in the LDPC decoder as the status of the decoder for adaptively selecting or setting decoding rules. In other words, as the current syndrome weight of the decoder changes in real-time, the adaptive controller of the LDPC decoder changes the decoding rules (e.g., flipping thresholds) in the decoder in real-time or on-the-fly during a decoding iteration. Alternatively or additionally, the adaptive LDPC decoder may use the status to select or set different decoding rules for decoding different blocks in the LDPC decoder. For example, a block in the decoder may include multiple bits in the LDPC with same or different types or degrees of bit-node. In one implementation, the adaptive controller can divide data to be decoded, or a whole LDPC code, into multiple M blocks. The adaptive controller can determine any suitable number of blocks of data (e.g., portions or subsets of data), which may range from at least two blocks to several blocks or dozens of blocks depending on complexity of the LDPC decoder. One block may include or correspond to one type of bits, while another block may include or correspond to another type of bits. Generally, a number to bit types in the data being decoded may be same as or different from a number of the blocks. Thus, an adaptive LDPC decoder may be configured to divide or form bits of the data into two types (T=2), yet with 3 different blocks (M=3). As an example, multiple blocks may cover the same type, such that two blocks cover a first type, and one block covers the second type. These are but a few examples of an adaptive LDPC decoder, which are described in detail along with others throughout this disclosure.

In various aspects of adaptive LDPC decoding, an adaptive LDPC decoder processes a first portion of data using first parameters effective to change a status of the LDPC decoder. The LDPC decoder selects second parameters of the LDPC decoder based on the status of the LDPC decoder. The LDPC decoder then processes a second portion of the data with the LDPC decoder using the second parameters and provides decoded data of the channel based on at least the processing the first portion of the data using the first parameters and the processing of the second portion of the data using the second parameters. In aspects, the adaptive decoder may determine multiple portions or subsets of data from the received data and process each of the multiple portions using adaptively selected or determined decoding parameters. By adaptively altering the decoding parameters based the status of the decoder, the adaptive LDPC decoder may decode channel data in fewer decoding iterations or with a higher success rate, thereby improving LDPC decoding performance.

The following discussion describes an operating environment, techniques that may be employed in the operating environment, and a System-on-Chip (SoC) in which components of the operating environment may be embodied. In the context of the present disclosure, reference is made to the operating environment or various components by way of example only.

Operating Environment

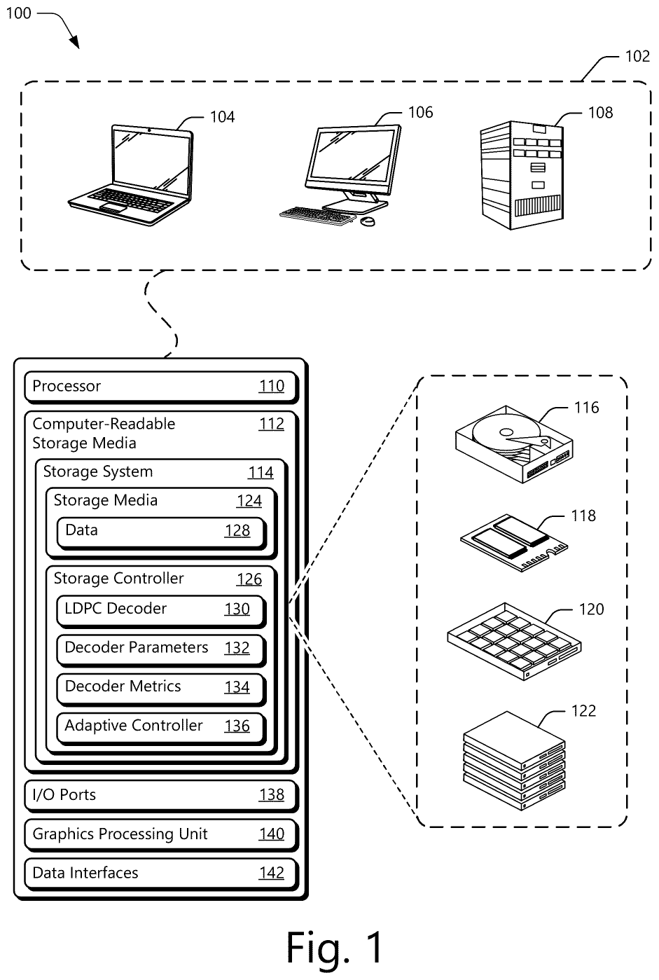

FIG. 1 illustrates an example operating environment 100 having a host system 102, capable of storing, accessing, or communicating various forms of data or information. Examples of a host system 102 may include a laptop computer 104, desktop computer 106, and server 108, any of which may be configured as a user device, computing device, or as part of a storage network, data storage center, cloud storage, or the like. Further examples of the host system 102 (not shown) may include a tablet computer, a set-top-box, a data storage appliance, a wearable smart-device, a television, a content-streaming device, a high-definition multimedia interface (HDMI) media stick, a smart appliance, a home automation controller, smart thermostat, Internet-of-Things (IoT) device, mobile-internet device (MID), a network-attached-storage (NAS) drive, aggregate storage system, gaming console, automotive entertainment device, automotive computing system, automotive control module (e.g., engine or power train control module), and so on. Generally, the host system 102 may communicate or store data for any suitable purpose, such as to enable functionalities of a particular type of device, provide a user interface, enable network access, implement gaming applications, play back media, provide navigation, edit content, provide data storage, or the like.

The host system 102 includes a processor 110 and computer-readable media 112. The processor 110 may be implemented as any suitable type or number of processors, either single-core or multi-core, for executing instructions or commands of an operating system or other applications of the host system 102. In aspects, the processors 110 of a host system may execute tenants, services, or workloads of a data storage system or data storage center. The computer-readable media 112 (CRM 112) includes memory (not shown) and a storage system 114 of the host system 102. The memory of the host system 102 may include any suitable type or combination of volatile memory or nonvolatile memory. For example, the volatile memory of host system 102 may include various types of random-access memory (RAM), dynamic RAM (DRAM), static RAM (SRAM), or the like. The non-volatile memory may include read-only memory (ROM), electronically erasable programmable ROM (EEPROM), solid-state storage media, or Flash memory.

The storage system 114 of the host system 102 may be configured as any suitable type of data storage system, such as a data storage center, storage device, storage drive, storage array, storage volume, or the like. Although described with reference to the host system 102, the storage system 114 may also be implemented separately as a standalone device or as part of a larger storage collective, such as a network-attached storage device, external storage drive, data storage center, server farm, or virtualized storage system (e.g., for cloud-based storage or services). Examples of the storage system 114 include a magnetic storage media drive 116, a non-volatile memory express (NVMe) solid-state drive (not shown), a peripheral component interconnect express (PCIe) solid-state drive 118, a solid-state drive 120 (SSD 120), and a storage array 122, which may be implemented with any combination of storage devices or storage drives.

The storage system 114 includes storage media 124 and a storage media controller 126 (storage controller 126) for managing various operations or functionalities of the storage system 114. The storage media 124 may include or be formed from non-volatile memory devices on which data 128 or information of the host system 102 is stored. The storage media 124 may be implemented with any type or combination of storage media, which may include optical storage media, magnetic storage media, holographic storage media, solid-state storage media, or the like. In aspects, a solid-state memory media may include one of Flash memory, NAND Flash, RAM, DRAM (e.g., for caching), SRAM, or the like. For example, the storage media 124 of the storage system 114 may include NAND Flash memory, single-level cell (SLC) Flash memory, multi-level cell (MLC) Flash memory, triple-level cell (TLC) Flash, quad-level cell Flash (QLC), NOR cell Flash, or any combination thereof. These memories, individually or in combination, may store data associated with a user, applications, a tenant, a workload, a service, and/or an operating system of the host system 102.

Generally, the storage controller 126 manages operation of the storage system 114 and enables the host system 102 to access the storage media 124 for data storage. The storage controller 126 may be implemented through any suitable combination of hardware, firmware, or software to provide various functionalities of the storage system 114. The storage controller 126 may also manage or administrate internal tasks or operations associated with the storage media 124, which may include data placement, data-to-block mapping, wear-leveling, data caching, data migration, garbage collection, thermal management (e.g., throttling), power management, or the like. As such, the storage controller 126 may receive read requests (e.g., host I/Os) from the host system 102 for data access and queue (or generate) internal commands (e.g., I/Os) associated with internal operations for the storage media 124. Generally, the storage controller 126 may perform media I/Os for access of the storage media 124 that correspond to scheduled host I/Os for data access (e.g., host write requests or read requests) and/or internal I/Os for internal operations or tasks associated with the storage media 124.

In this example, the storage controller 126 also includes an adaptive LDPC decoder 130 (LDPC decoder 130), decoding parameters 132, decoding metrics 134, and an adaptive decoder controller 136 (adaptive controller 136). Although not shown, the LDPC decoder 130 may include one or more processing blocks for implementing decoding of LDPC-encoded data, such as data received through a channel (e.g., storage channel or communication channel from a transmitter). In other configurations, the LDPC decoder 130 and adaptive controller 136 may be implemented in combination as an adaptive LDPC decoder. Thus, an adaptive LDPC decoder 130 may include a controller or control circuitry configured to implement various aspects of adaptive LDPC decoding. In some implementations, the decoding parameters 132 may include a set of decoding rules or thresholds stored to a lookup table, which may be implemented in hardware or a memory associated with the LDPC decoder 130.

In various aspects, the LDPC decoder 130 and/or adaptive controller 136 use the parameters 132 and metrics 134, which may be used to dynamically configure the parameters 132 for decoding data read from the storage media 124 of the storage system 114. Generally, the LDPC decoder 130 and adaptive controller 136 may implement adaptive decoding of ECC data read from the storage media 124 of the storage system 114. In some cases, the LDPC decoder 130 processes a first portion of data and the adaptive controller 136 obtains a status or metrics from the LDPC decoder 130 that change or update in response to processing the first portion of data. The adaptive controller 136 then selects or alters the parameters 132 based on the status or metrics of the LDPC decoder to use when decoding a second portion of the data. The selected decoding parameters provided by the adaptive controller 136 may enable the LDPC decoder 130 to decode the data in fewer decoding iterations or with a higher success rate, thereby improving LDPC decoding performance.

For example, the LDPC decoder 130 processes a first portion of data received from a channel using first parameters effective to change a status (e.g., syndrome weight) of the LDPC decoder. The adaptive controller 136 selects second parameters of the LDPC decoder, such as a bit-flip threshold or symbol-flip threshold, based on the status of the LDPC decoder. The LDPC decoder 130 then processes a second portion of the data with the LDPC decoder using the second parameters and provides decoded data of the channel based on at least the processing the first portion of the data using the first parameters and the processing of the second portion of the data using the second parameters. By adaptively altering the decoding parameters based the status of the decoder, the LDPC decoder may decode channel data in fewer decoding iterations or with a higher success rate, thereby improving LDPC decoding performance. This is but one example of adaptive LDPC decoding, other examples of which are described throughout the disclosure.

Returning to FIG. 1, the host system 102 may also include I/O ports 138, a graphics processing unit 140 (GPU 140), and data interfaces 142. Generally, the I/O ports 138 allow the host system 102 to interact with other devices, peripherals, or users. For example, the I/O ports 138 may include or be coupled with a universal serial bus, human interface devices, audio inputs, audio outputs, or the like. The GPU 140 processes and renders graphics-related data for the host system 102, such as user interface elements of an operating system, applications, or the like. In some cases, the GPU 140 accesses a portion of local memory to render graphics or includes dedicated memory for rendering graphics (e.g., video RAM) of the host system 102.

The data interfaces 142 of the host system 102 provide connectivity to one or more networks and other devices connected to those networks. The data interfaces 142 may include wired interfaces, such as Ethernet or fiber optic interfaces for communications over a local network, an intranet, or the Internet. Alternately or additionally, the data interfaces 142 may include wireless interfaces that facilitate communication over wireless networks, such as wireless LANs, wide-area wireless networks (e.g., cellular networks), and/or wireless personal-area-networks (WPANs). Any data communicated through the I/O ports 138 or the data interfaces 142 may be decoded using the aspects described herein. For example, a decoder of a data interface may be configured as an adaptive LDPC decoder and implement one or more of the techniques described to decode data received through a communication channel. Alternatively or additionally, data read from the storage system 114 of the host system 102 may be decoded and/or re-encoded for communication over the data interfaces 142 in accordance with one or more aspects of adaptive LDPC decoding.

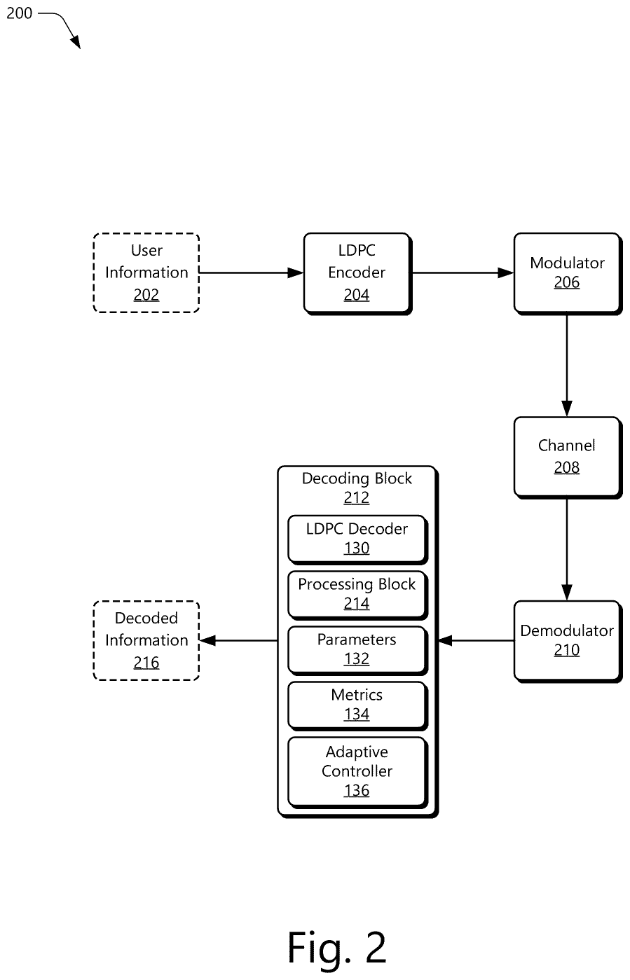

FIG. 2 illustrates at 200 an example of a data channel in which a decoder may implement aspects of adaptive LDPC decoding. Generally, the data channel illustrated may represent a medium through which data is transmitted to a receiver, or a medium which data is stored to and read from. In some cases, the data channel of FIG. 2 represents a medium in which encoded data is exposed to noise or interference, such as a wired medium, a wireless medium, an optical medium, a storage medium, or the like. Thus, noise or interference of the data channel may alter (e.g., introduce coding errors) any encoded and/or modulated data transmitted through or stored to the data channel by an electronic device. As described herein, aspects of adaptive LDPC decoding may improve decoder performance to correct such errors in fewer decoding iterations, reduced decoder latency, or with higher error-correction success rates.

In the context of the data channel of FIG. 2, user information 202 is encoded by an encoding mechanism, which in this example is illustrated as an LDPC encoder 204. The user information 202 may include any suitable type of information or data (e.g., message information, message vector) which may be grouped into units of k symbols, where each symbol may be binary, ternary, quaternary, or any other suitable type of data. For the sake of simplicity, implementations of the present disclosure will be described in terms of binary bits or symbols (e.g., LDPC codes over Galois Fields). For example, the described aspects can be applied to symbol-flipping decoders for non-binary LDPC codes, e.g., LDPC codes over Galois Fields GF(q), where the field size q is larger than two. Note that LDPC codes over GF(2) include the binary LDPC codes described throughout this disclosure. In the process of encoding the user information 202, any suitable codes may be used by an encoding block to achieve different results. In this example, the LDPC encoder 204 encodes the user information 202 using an LDPC code to produce one or more codewords (not shown) of encoded information. The LDPC encoder 204 may be configured to implement various LDPC encoding schemes or produce codewords of one or more predetermined lengths. In aspects, the LDPC encoder 204 provides or sends the codewords to a modulator 206, which prepares codewords for transmission on a channel 208. By way of example, the modulator 206 can modulate the codewords using phase-shift keying, frequency-shift keying, quadrature amplitude modulation, or any suitable modulation technique to convert the codewords into one or more information-carrying signals. Encoded data or modulated data may then be written or stored to the channel 208, which represents media through which the information-carrying signals travel (e.g., optical or electrical signals) or to which the information-carrying signals are stored. For example, the channel 208 may represent a wired or wireless medium of a communication system, an optical communication system (e.g., fiber or free space), a solid-state media (e.g., RAM, ROM), a magnetic media (e.g., a hard disk, tape drive), or an optical media (e.g., DVD, holographic) storage medium in which the information-carrying signals may be stored.

Due to interference signals and other types of noise and phenomena, the channel 208 may affect or corrupt the information-carrying signals generated by the modulator 206. Thus, a waveform of the information-carrying signals received by a demodulator 210 may be different from an original waveform of the information-carrying signals entering the channel 208. The demodulator 210 demodulates the information-carrying signals received through or from the channel 208 and may implement filtering, multiplication by periodic functions, or any suitable demodulation technique corresponding to a type of modulation implemented by the modulator 206. Due to the non-ideal nature of the channel 208 (e.g., noise), the result of the demodulation may include a demodulated bit or bit stream (e.g., received vectors) that may contain errors due to channel corruption.

To recover data from the demodulated signals (e.g., received vectors), a decoding block 212 may decode the bit stream or vectors to detect and/or remove errors resulting from the channel 208. In this example, the decoding block 212 includes an adaptive LDPC decoder 130, a processing block 214, decoding parameters 132 (parameters 132), decoding metrics 134 (metrics 134), and adaptive controller 136. Generally, the LDPC decoder 130 may detect and/or correct errors in data received from the channel, such as encoded information read from a storage medium. The LDPC decoder 130 may implement an iterative decoding algorithm (e.g., flooding decoding, layered decoding, bit-flipping decoding, symbol-flipping decoding) to detect and/or correct errors in demodulated data or vectors provided by the demodulator 210. In aspects, the LDPC decoder 130 is configured as a bit-flipping decoder to iteratively decode noisy data received from the channel 208. The LDPC decoder 130 may provide information to the processing block 214, such as an LDPC vector or the bit-flip vector. Generally, the processing block 214 can receive any relevant information from the LDPC decoder 130. In some cases, the processing block 214 receives information from the LDPC decoder 130 for computations performed during an iteration by the decoder. In some implementations, the LDPC information is received in vector form (e.g., LDPC vector), which may include or correspond to a number of unsatisfied checks vector (NUC vector) for each bit-node or for each group of bit-nodes (e.g., bits of a codeword) in the LDPC decoder. In aspects, the processing block 214 may translate the LDPC vector 508 (or NUC vector) and the bit flip vector 510 into decoding metrics 134 (e.g., decoder status) of the LDPC decoder 130, which may include NUC states, where a NUC state can indicate the number of unsatisfied checks for a bit-node or a block of bit-nodes.

When utilizing such an iterative algorithm, the LDPC decoder 130 may perform several iterations of bit-flipping operations until an output of the adaptive LDPC decoder 130 converges to a valid codeword. As described herein, during the decoding process, the adaptive controller 136 may select or alter the decoding parameters 132 based on the decoding metrics 134 (e.g., status, state information) of the LDPC decoder 130 during an iteration of decoding. For example, the adaptive controller 136 may obtain metrics 134 (e.g., LDPC state information, syndrome weight) from the LDPC decoder 130 during an iteration of decoding and select one or more different bit-flip thresholds for decoding remaining bits in the iteration of the decoding process. When the LDPC decoder 130 converges to a valid codeword or reaches a maximum iteration limit, the adaptive LDPC decoder 130 provides decoded information 216, which may correspond to the original user information 202 sent through the channel 208 if error correction by the adaptive LDPC decoder is successful.

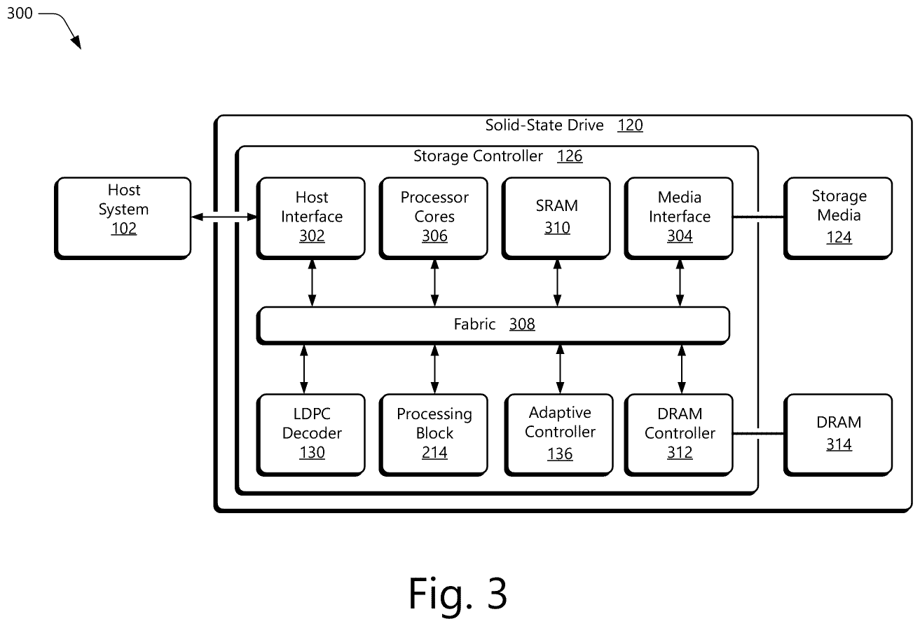

FIG. 3 illustrates at 300 an example configuration of a storage system that includes an adaptive LDPC decoder implemented in accordance with one or more aspects. In this example, a storage controller 126 of a storage system 114 includes instances of an LDPC decoder 130, a processing block 214, and an adaptive controller 136, which may be implemented as or be a part of a decoding block of the storage controller 126. The storage controller 126 may be configured to manage or enable access of a host system 102 to any suitable type of storage media 124, and may include or implement corresponding functions, such as a Flash translation layer (not shown) or the like. The adaptive decoder 130 and/or adaptive controller 136 may interact with the storage controller 126 or components thereof to implement aspects of adaptive LDPC decoding.

In this example, the LDPC decoder 130 and adaptive controller 136 are illustrated in the context of a storage system 114 that is implemented as an instance of a solid-state storage drive (SSD) 120. The SSD 120 may be coupled to any suitable host system 102 and implemented with storage media 124 that includes multiple NAND Flash dies (not shown). Alternatively, the example storage system may be implemented with magnetic storage media, an optical storage media, or the like. Although illustrated as components of the SSD 120, the adaptive LDPC decoder 130, processing block 214, and/or adaptive controller 136 may be implemented separately from or external to the storage system 114. In some cases, the adaptive LDPC decoder 130 or adaptive controller 136 are implemented as part of a storage media accelerator or aggregate storage controller coupled between the host system 102 and one or more storage systems 114.

Generally, operations of the SSD 120 are enabled or managed by an instance of the storage controller 126, which in this example includes a host interface 302 to enable communication with the host system 102 and a media interface 304 to enable access to the storage media 124. The host interface 302 may be configured to implement any suitable type of storage interface or protocol, such as serial advanced technology attachment (SATA), universal serial bus (USB), PCIe, advanced host controller interface (AHCI), NVMe, NVM-over Fabric (NVM-OF), NVM host controller interface specification (NVMHCIS), small computer system interface (SCSI), serial attached SCSI (SAS), secure digital I/O (SDIO), Fibre channel, any combination of these protocols (e.g., an M.2 or next generation form factor (NGFF) combined interface), or the like. Alternately or additionally, the media interface 304 may implement any suitable type of storage media interface, such as a Flash interface, a Flash bus channel interface, a NAND channel interface, a physical page addressing (PPA) interface, a read/write channel interface (e.g., for magnetic media), or the like.

In various aspects, components of the storage controller 126 provide a data path through the controller between the host interface 302 to the host system 102 and the media interface 304 to the storage media 124. In this example, the storage controller 126 includes processor cores 306 for executing a kernel, firmware, or a driver to implement functions of the storage controller 126. In some cases, the processor cores 306 may also execute processor-executable instructions to implement the adaptive LDPC decoder 130 or the adaptive controller 136 of the storage controller 126. Alternately or additionally, the adaptive LDPC decoder 130 or the adaptive controller 136 may execute from or run on ML-specific hardware, AI engines, or processor cores.

As shown in FIG. 3, a fabric 308 of the storage controller 126, which may include control and data buses, operably couples and enables communication between the components of the storage controller 126. For example, the adaptive LDPC decoder 130 or processing block 214 may communicate with the host interface 302, processor cores 306 (e.g., firmware), or media interface 304 to exchange data, decoding information, commands, or I/Os within the storage controller 126. In aspects, the adaptive LDPC decoder 130 may implement adaptive decoding of information (e.g., codewords) read from the storage media 124, which may be performed responsive to read requests by the host system 102. Generally, the adaptive LDPC decoder 130 and processing block 214 may use the adaptive controller 136 to implement aspects of adaptive decoding in which decoding rules or thresholds of the LDPC decoder are dynamically adjusted or selected during a decoding iteration based on a status, state information, or metrics of the LDPC decoder to provide error detection and/or error correction for data read from the storage media 124. A static random-access memory 310 (SRAM 310) of the storage controller 126 can store processor-executable instructions or code for firmware or drivers of the storage controller, which may be executed by the processor cores 306. The storage controller 126 may also include a dynamic random-access memory (DRAM) controller 312 and an associated DRAM 314 for storage or caching various data as the storage controller 126 moves data between the host system 102, storage media 124, and other components of the storage controller.

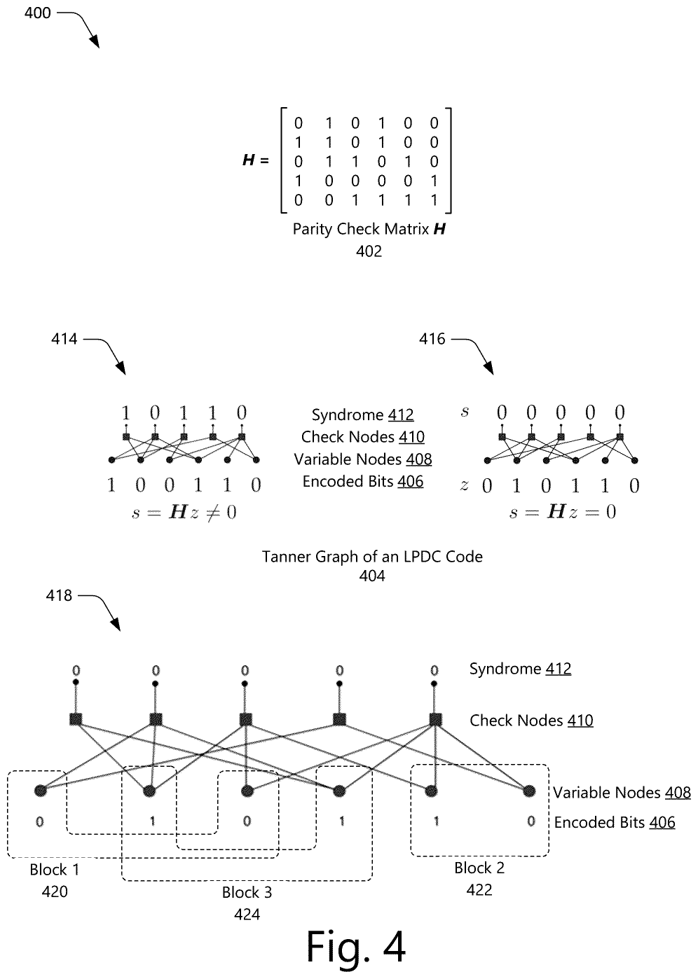

FIG. 4 illustrates at 400 example Tanner graphs of LDPC data that may be processed with an adaptive LDPC decoder. In the context of a storage system or a communication system, data received from a channel may include encoded data or codewords that the LDPC decoder 130 (not shown) attempts to decode to provide or reproduce the original data that is written or transmitted to the channel. In the context of a storage system, when data is read from storage media, such as NAND Flash memory, the data may include bit errors (e.g., 0s are flipped to 1s, 1s are flipped to 0s). Generally, an encoder can apply an LDPC code to data before the data is transmitted through the communication channel (e.g., before writing to storage media), and the adaptive LDPC decoder 130 can decode the LDPC-encoded data after the encoded data is received from the communication channel (e.g., after reading from the storage media). In aspects, the adaptive LDPC decoder is implemented as a bit-flipping LDPC decoder, which can flip bits when decoding the encoded data to potentially flip incorrect bits to original values as transmitted or written to the channel.

By way of example and as shown in FIG. 4, an LDPC code is typically defined by a parity check matrix H 402, such as for a codeword of encoded bits or the like. An LDPC code may also be represented by a bipartite Tanner graph 404 of encoded bits 406, where each bit “1” in the parity check matrix H 402 is represented by an edge between a corresponding variable node 408 (column) and a corresponding check node 410 (row). In some cases, a variable node 408 may also be referred to as a bit node. During the decoding process, the adaptive LDPC decoder 130 can compute a syndrome vector 412 (e.g., a ‘syndrome’) as shown in Equation 1.

Syndrome=H·z, where z represents the received bit vector Equation 1: LDPC Syndrome

For example, the received bit vector z may represent a noisy version of encoded data written or stored to the channel, such as solid-state or magnetic storage media. A weight of the syndrome vector may be referred to as the syndrome weight, which can be calculated as a sum of the syndrome vector entries, which are 0s and 1s. As shown in FIG. 4, each circular node corresponds to an encoded bit or a variable node 408. A number of lines between one variable node 408 (or bit node) and a square check node 410 can be called a “type of bit”, which may also be referred to as degree of bit-node (or degree of variable-node). This type of bit or degree of bit-node equals a number of 1s in each column of the parity check matrix H 402 that corresponds to the Tanner graph 404. For example, as shown in FIG. 4, the variable node 408 (leftmost) connects with two lines to respective check nodes 410, meaning this variable node is a type-2 (degree-2) node, and the number of 1s in the 1st column of the parity check matrix H is two. The next variable node connects with three lines to respective check nodes 410, meaning it is a type-3 (degree-3) node, and the number of 1s in the 2nd column of the parity check matrix H is 3. Generally, aspects of adaptive LDPC encoding may relate or be of interest for LDPC codes that may have one, two, or three or more different bit types, such that the methodology described herein may apply to all such LDPC code configurations. Thus, the described aspects of adaptive decoding may be applied to symbol-flipping decoders, such as Galois Field-based symbols capable of four states, eight states, and so forth. As shown at 414, when received or read bits are noisy, typically a syndrome vector for the bits is a non-zero vector and a syndrome weight is greater than 0. Alternatively, when the received or read bits are without any noise, the syndrome vector is a zero vector (e.g., entries are zeros) and the syndrome weight is 0. In aspects, the LDPC decoder 130 and adaptive controller 136 may interactively process (e.g., flip bits) noisy bits of data or a codeword until the syndrome 412 or the syndrome weight of the codeword approaches zero, meaning that errors in the received or read bits have been corrected.

In aspects of adaptive decoding, the LDPC decoder 130 and adaptive controller 136 implement an adaptive decoding process in which bit-flipping or symbol-flipping parameters (e.g., rules, thresholds) of the decoder are dynamically updated during an iteration of the decoding process. In some implementations of adaptive decoding, the decoding parameters (e.g., flipping thresholds) change adaptively based on the status (e.g., metrics) of the decoder on a per-block basis during the decoding (e.g. real-time status within each decoding iteration) instead of the decoder using fixed rules values throughout a given iteration for all bits in the LDPC code of the data being decoded.

The status of the decoder may include one or more of a syndrome weight, a column weight of a parity check matrix, a LDPC code being decoded, a bit-position of a bit or variable node, an iteration index, a block index, whether a bit (or symbol) flipped or not flipped (e.g., flip status), and so on. Thus, in addition to an iteration number or a flip status of a bit, the adaptive controller 136 may set or select decoding parameters (e.g., the flipping thresholds) based on a real-time status of the decoder. In some aspects, the adaptive controller uses a sum of syndrome values (current syndrome weight, parity check constraints) in the LDPC decoder 130 as the status of the decoder for adaptively selecting or setting decoding rules. In other words, as the current syndrome weight of the decoder changes in real-time, the adaptive controller 136 changes the decoding parameters (e.g., flipping thresholds) in the decoder in real-time or on-the-fly during a decoding iteration.

In the context of blocks of variable nodes 408 or bit nodes, the LDPC decoder 130 or adaptive controller 136 can divide a matrix or graph of variable bits 408 or data bits into blocks or other suitable subsets of variable bits. For example, a block in the decoder may include multiple bits in the LDPC graph (e.g., data set being decoded) with same or different types or degrees of bit-node. In one implementation, the adaptive controller 136 divides data to be decoded, or a whole LDPC code, into multiple M blocks. One block may include or correspond to one type of bits, while another block may include or correspond to another type of bits. Generally, a number of bit types “T” in the data being decoded may be same as or different from a number of the blocks “M” into which the data is divided. Thus, an adaptive LDPC decoder may be configured to divide or form bits of the data into two types (T=2), yet with 3 different blocks (M=3). As an example, multiple blocks may cover the same type, such that two blocks cover a first bit type, and one block covers the second bit type. As an example, consider the variable nodes shown at 418 in FIG. 4 which are divided into three block types. In this example, block 1 420 includes a first subset of type-2 variable nodes 408, block 2 422 includes a second subset of type-2 variable nodes 408 of different bit position (or bit position ranges, e.g., bits 1-3, 4-6, etc.), and block 3 424 includes a subset of type-3 variable nodes 408, and so forth.

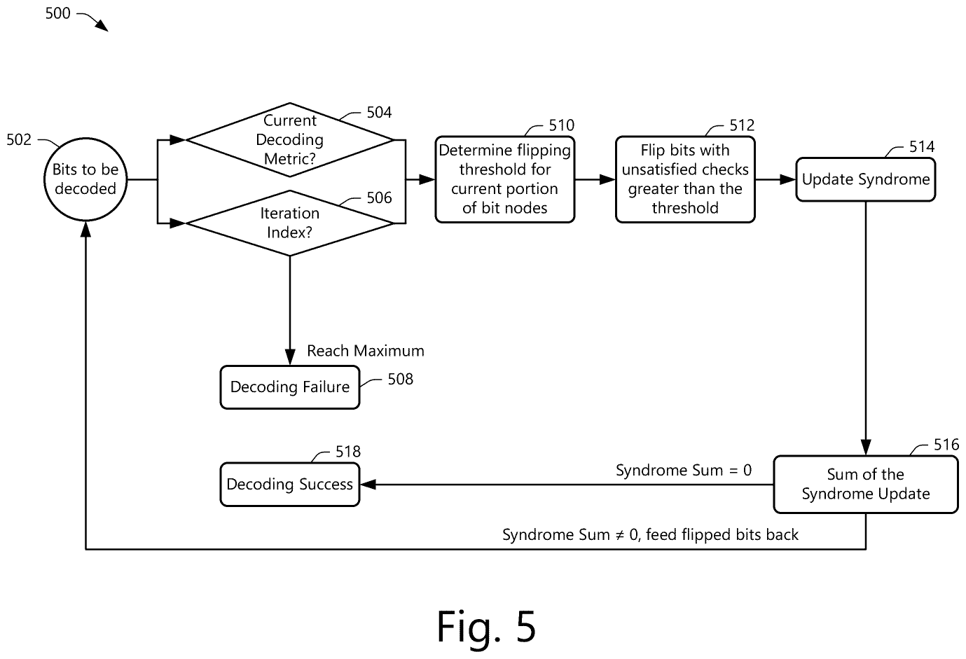

FIG. 5 illustrates at 500 an example algorithm that an adaptive LDPC decoder may implement in accordance with various aspects. Although described in reference to a bit-flipping decoder, the aspects of the algorithm 500 may also be applied to other types of decoders, including symbol-flipping decoders or the like. Generally, a bit-flipping decoder can implement a hard decision decoding algorithm for LDPC codes. By way of example, at a decoding iteration number i, a decoder or processing block computes a number of unsatisfied check nodes connected to a variable node j (e.g., variable node 408), which may be denoted as Uⱼ (for the variable node j). The decoder or processing block then compares this number with a bit-flipping threshold (tᵢ), and if the number of unsatisfied check nodes Uⱼ exceeds the threshold, the decoder flips the variable node j (flips a value of bit j), otherwise keeps the bit value for the variable node (does not flip the value of bit j). During an iteration, an adaptive decoder can perform this bit-flipping comparison for respective bits of a subset or block of bits using different decoding parameters 132 (e.g., thresholds).

In aspects, the adaptive controller 136 can alter, select, or modify the decoding parameters based on a status of the decoder, which may include one or more various metrics 134. For example, the adaptive controller 136 may be configured to select decoding parameters 132 based on a syndrome weight and a bit-flip status of a variable node. In some implementations, the adaptive controller includes or has access to a table of decoding parameters (e.g., bit-flip thresholds) that are accessed or selected based on the syndrome weight and the bit-flip status of the variable node. Thus, the table may include a range of syndrome weight and a threshold pair (t₁₍ᵢ₎, t₂₍ᵢ₎) that are selected based on a current syndrome weight of the decoder and whether the variable node j is equal to the received bit j of a channel. In the context of the present example, the adaptive controller selects a threshold pair based on the current syndrome weight of the decoder and then compares the number of unsatisfied check nodes (Uⱼ) connected to the variable node j with one of the threshold pair values based on whether the variable node j has been flipped from the original value (t₁₍ᵢ₎, flipped threshold) or has not been flipped (t₂₍ᵢ₎, un-flipped threshold) as received by the decoder. Based on the comparison, the decoder or processing block flips the value of the bit node j if the number of unsatisfied check nodes Uⱼ exceeds the selected threshold, otherwise keeps the bit value for the variable node (does not flip the value of bit j). The LDPC decoder 130 may continue this process throughout the decoding iteration, selecting different bit-flipping thresholds for variable nodes based on the syndrome weight of the decoder and a bit-flip status of the variable node. Alternatively or additionally, the adaptive controller 136 may use any combination of decoding metrics, such as two or more of the syndrome weight, a bit-position of a bit or variable node of the data, which LDPC code is implemented by the LDPC decoder, a degree of one or more bits of the data (e.g., type of bit), a block index of the LDPC decoder, an iteration index of the LDPC decoder, and so forth. At the end of the iteration, the LDPC decoder or adaptive controller computes a sum of the syndrome updates and the decoded output (e.g., decoded word) is stored. These iterations of decoding may be repeated for several iterations (i=1, 2, 3, . . . , K) until the sum of the syndrome (syndrome weight) reaches 0 or a maximum allowed iteration number K is reached.

Returning to the algorithm illustrated in FIG. 5, an adaptive LDPC decoder can implement the operations of the algorithm to decode data received from a channel, such as a storage channel or communication channel. At 502, the adaptive LDPC decoder receives bits to be decoded from the channel and, in some implementations, divides the graph or matrix of the bits into blocks of bits for processing during an iteration of decoding. The adaptive decoder may determine or divide the received data into multiple subsets or portions for decoding. For example, the adaptive decoder may divide the data into two portions, three portions, four portions, and so on. At 504, the adaptive LDPC decoder or adaptive controller determines a current decoding metric, which may include a syndrome weight, column weight of the parity check matrix, a LDPC code being decoded, a block index, whether a bit (or symbol) flipped or not flipped (e.g., flip status), or the like. At 506, the adaptive LDPC decoder may also determine an iteration index for the current iteration of decoding being performed by the decoder, which if exceeded at 508, may indicate a decoding failure to complete decoding of the bits after several iterations. Otherwise, the adaptive LDPC decoder or adaptive controller determines at 510 a flipping threshold for the current portion (e.g., subset or block) of bit nodes being decoded.

At 512, the adaptive LDPC decoder flips bits of the current portion of bits with a number of unsatisfied checks greater than the threshold and then updates the syndrome of the decoder at 514. Note that the syndrome of the decoder may change or update after each bit is flipped, and the decoder may track the syndrome update or syndrome weight on a per-bit-flip basis, which may enable dynamic adjustment of decoding rules or thresholds. Thus, the adaptive decoder may process multiple portions of received data or bits (e.g., three to six subsets of data) using multiple respective sets of decoding parameters (e.g., three to six sets of adaptively selected decoding parameters). At 516, the adaptive LDPC decoder sums the syndrome update at the end of the decoding iteration and if the syndrome sum equals zero, the adaptive LDPC decoder provides the decoded data at 518 as a decoding success. Otherwise, the adaptive LDPC decoder feeds the current iteration of the decoded bits including the flipped bits back for another iteration of decoding by the adaptive LDPC decoder. This algorithm may repeat until the syndrome sum reaches zero or the adaptive LDPC decoder encounters the maximum number of decoding iterations allowed.

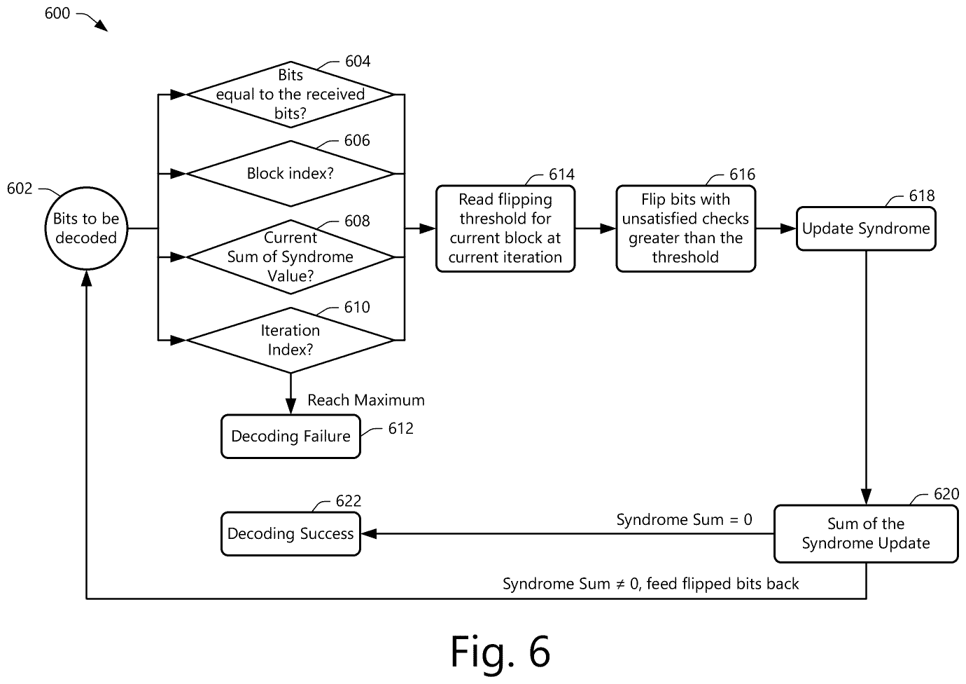

As another example, consider FIG. 6 which illustrates at 600 an algorithm for adaptive LDPC decoding with thresholds adjusted based on a syndrome of the LDPC decoder. Although described in reference to a bit-flipping decoder, the aspects of the algorithm 600 may also be applied to other types of decoders, including symbol-flipping decoders or the like. At 602, the adaptive LDPC decoder receives bits to be decoded from the channel and, in some implementations, divides the graph or matrix of the bits into blocks of bits for processing during an iteration of decoding. At 604, the adaptive LDPC decoder or adaptive controller determines whether the bits are equal to the received bits or if the bits have been flipped from an original value of the bit when received (e.g., bit-flip status). At 606, the adaptive decoder determines a block index for the bits currently being decoded and a current sum of the syndrome value at 608. Alternatively or additionally, the adaptive decoder may determine block indices based on a respective bit-position of the bit nodes or variable nodes of the graph. At 610, the adaptive LDPC decoder may also determine an iteration index for the current iteration of decoding being performed by the decoder, which if exceeded at 612, may indicate a decoding failure to complete decoding of the bits after several iterations. Otherwise, at 614 the adaptive LDPC decoder or adaptive controller reads or accesses a flipping threshold for the current block of bits at the current iteration of decoding. Thus, the adaptive LDPC decoder may obtain a bit-flipping (or symbol-flipping) threshold based on a syndrome weight, bit-flip status, and block index of a current subset of bits being decoded.

At 616, the adaptive LDPC decoder flips bits of the current block of bits with a number of unsatisfied checks greater than the threshold and then updates the syndrome of the decoder at 618. Note that the syndrome of the decoder may change or update after each bit is flipped, and the decoder may track the syndrome update or syndrome weight on a per-bit-flip basis, which may enable dynamic adjustment of decoding rules or thresholds. At 620, the adaptive LDPC decoder sums the syndrome update at the end of the decoding iteration and if the syndrome sum equals zero, the adaptive LDPC decoder provides the decoded data at 618 as a decoding success. Otherwise, the adaptive LDPC decoder feeds the current iteration of the decoded bits including the flipped bits back for another iteration of decoding by the adaptive LDPC decoder. This algorithm may repeat until the syndrome sum reaches zero or the adaptive LDPC decoder encounters the maximum number of decoding iterations allowed.

As an example, consider a decoding process that includes two iterations of decoding an LDPC code with aspects of adaptive decoding. In this example, assume an adaptive LDPC decoder is decoding an LDPC code with length N, and bits of this LDPC code have two types (Type A (e.g., degree-3) and Type B (e.g., degree-2)), which are divided into three blocks (M=3). Assume, for this example, that Type A bits are covered by a first block and Type B bits are covered by a second block and a third block. When the adaptive LDPC decoder performs the bit-flipping decoding, at the decoding iteration i, for each block in this decoding iteration, the adaptive LDPC decoder compares the number of unsatisfied check nodes (Uj) connected to the variable node j with a threshold selected based on a current syndrome weight. In some implementations, the adaptive LDPC decoder selects, based on the syndrome weight, the threshold from a threshold table stored to or accessible by the decoder. In the context of the current example, at a first iteration (iteration index=1), assume that the adaptive LDPC decoder decodes Type A bits. Because Type A bits are covered by one block (block 1), the adaptive LDPC decoder processes this one block by accessing thresholds associated with a block index of one. By way of example, consider Table 1 in which thresholds for block index 1 are accessible based on ranges of syndrome weight and bit-flip status (t₁ or t₂).

TABLE 1
Bit-Flip Thresholds for Block Index 1

| Iteration | Block | Syndrome | Threshold | Threshold |
|---|---|---|---|---|
| Index i | Index | Weight | t₁₍ᵢ₎ | t₂₍ᵢ₎ |
| 1 | 1 | 0~25 | a_{1, 1} | b_{1, 1} |
| 1 | 1 | . . . | . . . | . . . |
| 1 | 1 | 175~200 | a_{1, k-1} | b_{1, k-1} |
| 1 | 1 | 200~225 | a_{1, k} | b_{1, k} |
| 1 | 1 | 225~250 | a_{1, k+1} | b_{1, k+1} |
| 1 | 1 | . . . | . . . | . . . |
| 1 | 1 | 900~1000 | a_{1, Q-1} | b_{1, Q-1} |
| 1 | 1 | 1000~10000 | a_{1, Q} | b_{1, Q} |

When processing this block of bit nodes, the adaptive LDPC decoder would access and use a bit-flipping threshold based on the current status or metrics of the decoder. For example, if the syndrome weight of the decoder is between 175 and 200, the adaptive LDPC decoder uses threshold pair (a_{1,k-1},b_{1,k-1}) for bit nodes of block 1, if the syndrome weight of the decoder is between 200 and 225, the adaptive LDPC decoder uses threshold pair (a_{1,k}, b_{1,k}) for bit nodes of block 1, if the syndrome weight of the decoder is between 225 and 250, the adaptive LDPC decoder uses threshold pair (a_{1,k+1}, b_{1,k+1}) for bit nodes of block 1, and so forth. Based on the threshold entry selected from the table, the adaptive LDPC decoder performs the bit-flipping using the threshold where if Uⱼ is larger than the selected threshold, the decoder flips the bit, otherwise, the decoder keeps the bit value. In aspects, this continues as the adaptive LDPC decoder updates the syndrome weight and selects or changes thresholds on-the-fly.

After the first iteration is complete, the adaptive LDPC decoder advances to a second iteration (iteration index=2), during which Type B bits are decoded as block 2 bits and block 3 bits of the LDPC code. Because the Type B bits are covered by two different blocks, the adaptive LDPC decoder may access two different tables with different block indexes, examples of which are illustrated as Table 2 for Block Index 2 and Table 3 for Block Index 3.

TABLE 2
Bit-Flip Thresholds for Block Index 2

| Iteration | Block | Syndrome | Threshold | Threshold |
|---|---|---|---|---|
| Index i | Index | Weight | t₁₍ᵢ₎ | t₂₍ᵢ₎ |
| 2 | 2 | 0~25 | a_{2, 1} | b_{2, 1} |
| 2 | 2 | . . . | . . . | . . . |
| 2 | 2 | 175~200 | a_{2, k-1} | b_{2, k-1} |
| 2 | 2 | 200~225 | a_{2, k} | b_{2, k} |
| 2 | 2 | 225~250 | a_{2, k+1} | b_{2, k+1} |
| 2 | 2 | . . . | . . . | . . . |
| 2 | 2 | 900~1000 | a_{2, Q-1} | b_{2, Q-1} |
| 2 | 2 | 1000~10000 | a_{2, Q} | b_{2, Q} |

In the context of the second iteration and for Block Index 2, the adaptive LDPC decoder would access Table 2 and use a bit-flipping threshold based on the current status or metrics of the decoder. For example, if the syndrome weight of the decoder is between 175 and 200, the adaptive LDPC decoder uses threshold pair (a_{2,k-1}, b_{2,k-1}) for bit nodes of block 2, if the syndrome weight of the decoder is between 200 and 225, the adaptive LDPC decoder uses threshold pair (a_{2,k}, b_{2,k}) for bit nodes of block 2, if the syndrome weight of the decoder is between 225 and 250, the adaptive LDPC decoder uses threshold pair (a_{2,k+1}, b_{2,k+1}) for bit nodes of block 2, and so forth.

TABLE 3
Bit-Flip Thresholds for Block Index 3

| Iteration | Block | Syndrome | Threshold | Threshold |
|---|---|---|---|---|
| Index i | Index | Weight | t₁₍ᵢ₎ | t₂₍ᵢ₎ |
| 2 | 3 | 0~25 | a_{3, 1} | b_{3, 1} |
| 2 | 3 | . . . | . . . | . . . |
| 2 | 3 | 175~200 | a_{3, k-1} | b_{3, k-1} |
| 2 | 3 | 200~225 | a_{3, k} | b_{3, k} |
| 2 | 3 | 225~250 | a_{3, k+1} | b_{3, k+1} |
| 2 | 3 | . . . | . . . | . . . |
| 2 | 3 | 900~1000 | a_{3, Q-1} | b_{3, Q-1} |
| 2 | 3 | 1000~10000 | a_{3, Q} | b_{3, Q} |

For bits of Block Index 3, which may be processed before, after, or in parallel with the bits of Block Index 2, the adaptive LDPC decoder accesses Table 3 and use a bit-flipping threshold based on the current status or metrics of the decoder. For example, if the syndrome weight of the decoder is between 175 and 200, the adaptive LDPC decoder uses threshold pair (a_{3,k-1}, b_{3,k-1}) for bit nodes of block 3, if the syndrome weight of the decoder is between 200 and 225, the adaptive LDPC decoder uses threshold pair (a_{3,k}, b_{3,k}) for bit nodes of block 3, if the syndrome weight of the decoder is between 225 and 250, the adaptive LDPC decoder uses threshold pair (a_{3,k+1}, b_{3,k+1}) for bit nodes of block 3, and so forth. Continuing the present example, and for each block of a given iteration, the adaptive LDPC decoder can use different tables based on the status and/or metrics of the decoder as the adaptive LDPC decoder implements the bit-flipping algorithm to decode the LDPC code. Thus, for iterations beyond the second iteration, the adaptive LDPC decoder proceeds in the same fashion, by accessing threshold tables that correspond to a particular iteration and the particular block (or blocks) being decoded during that iteration. As described herein, the adaptive LDPC decoding may proceed until the syndrome weight reaches zero or the adaptive LDPC decoder reaches a maximum limit of iterations (K).

Techniques for Adaptive LDPC Decoding

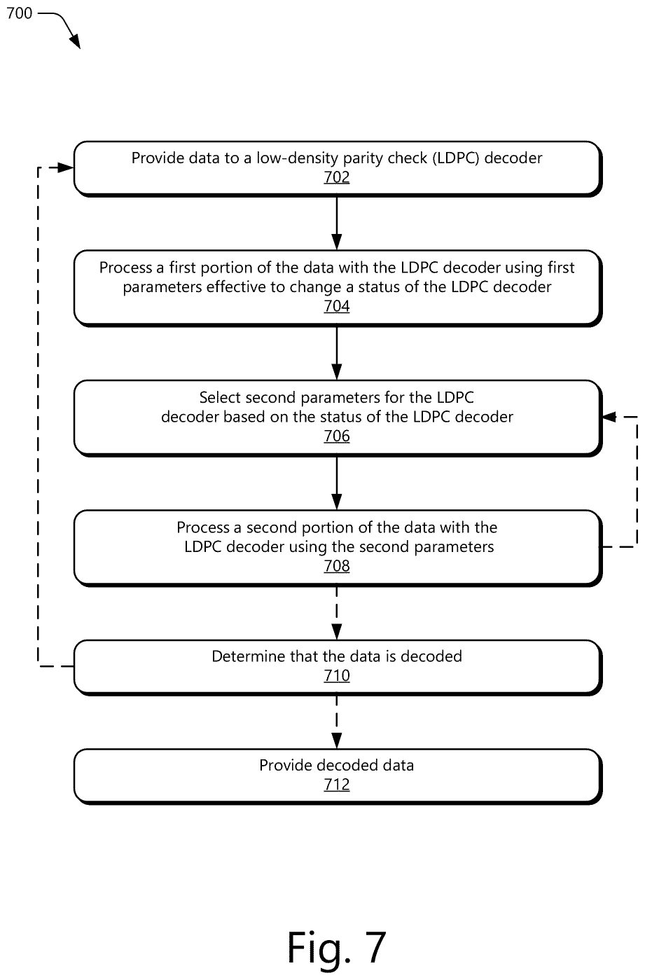

The following discussion describes techniques for adaptive LDPC decoding, which may enable an LDPC decoder to decode channel data in fewer decoding iterations or with a higher success rate, thereby improving LDPC decoding performance. These techniques may be implemented using any of the environments and entities described herein, such as the LDPC decoder 130 and adaptive decoder controller 136. These techniques include various methods illustrated in FIGS. 7-10, each of which is shown as a set of operations that may be performed by one or more entities.

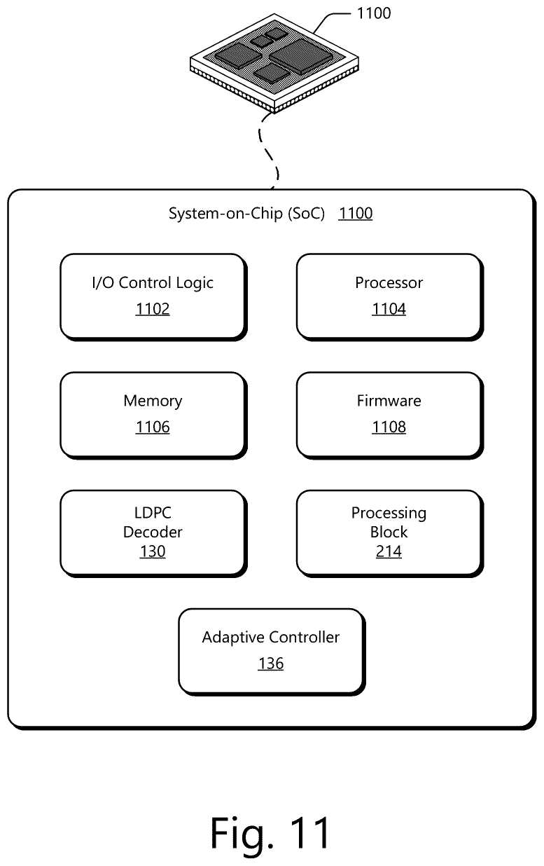

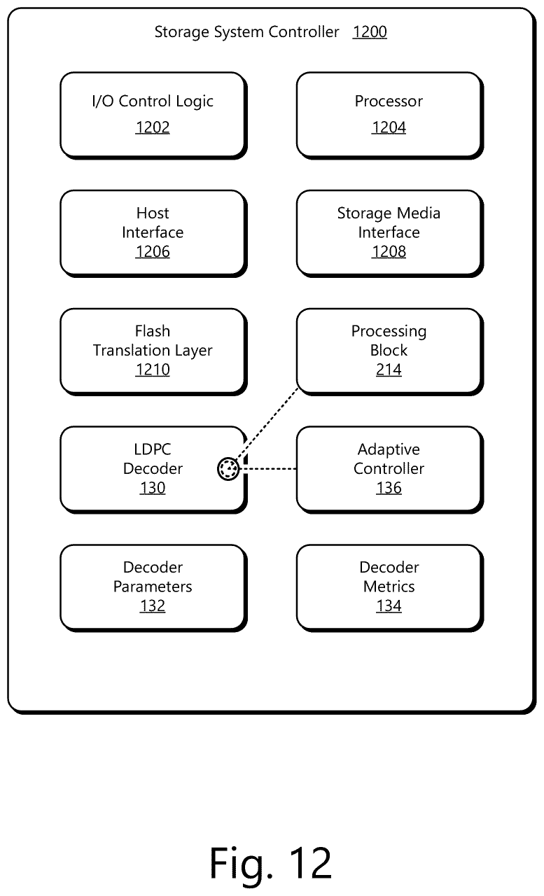

These methods are not necessarily limited to the orders of operations shown in the associated figures. Rather, any of the operations may be repeated, skipped, substituted, or re-ordered to implement various aspects described herein. Further, these methods may be used in conjunction with one another, in whole or in part, whether performed by the same entity, separate entities, or any combination thereof. For example, the methods may be combined to implement adaptive LDPC decoding to adaptively set, based on decoder status, parameters (e.g., bit flip thresholds) of an LDPC decoder to decode channel data in fewer decoding iterations or with a higher success rate, thereby improving LDPC decoding performance. In portions of the following discussion, reference will be made to the operating environment 100 of FIG. 1 and various entities or configurations of FIGS. 2-6 by way of example. Such reference is not to be taken as limiting described aspects to the operating environment 100, entities, or configurations, but rather as illustrative of one of a variety of examples. Alternately or additionally, operations of the methods may also be implemented by or with entities described with reference to the System-on-Chip of FIG. 11 and/or the storage system controller of FIG. 12.

FIG. 7 depicts an example method 700 for adaptive LDPC decoding in accordance with various aspects, including operations performed by or with an LDPC decoder 130, decoding parameters 132, decoding metrics 134, or an adaptive controller 136 associated with the adaptive LDPC decoder.

At 702, data is provided to an LDPC decoder, which can be configured as an adaptive LDPC decoder or include an adaptive controller. The data may be received from a channel, such as a storage channel or a communication channel. For example, the data may be received from a storage channel via a storage media interface or from a communication channel via a transceiver. Due to noise in the channel, one or more bits of the data (e.g., one or more bits of a data codeword) may be flipped or incorrect. Thus, the bits of the received data or read data may include flipped bits or bit errors in an ECC coding of the data. In aspects, the adaptive LDPC decoder divides or apportions the data of the graph or matrix into multiple portions or subsets (e.g., blocks) for processing during an iteration of decoding.

At 704, the LDPC decoder processes a first portion of the data using first parameters effective to change a status of the decoder. To process the first portion of the data, the adaptive LDPC decoder flips bits or symbols of the first portion of bit nodes or variable nodes based on the first parameters. The first parameters may include decoding rules or decoding thresholds by which the bits of the first portion of the data are processed. The LDPC decoder may select the first parameters for decoding the first portion of the data based on one or more metrics of the decoder, which may include a syndrome weight, bit-flip status, a column weight, block index, or the like. The change in status of the decoder may include an update to the syndrome weight of the decoder, which may change or update each time a bit or symbol of the LDPC code is flipped from a current value to a different value.

At 706, the LDPC decoder selects second parameters for the LDPC decoder based on the status of the decoder. The second parameters may include decoding rules or decoding thresholds by which the bits of the first portion of the data are processed. The LDPC decoder may select the second parameters for decoding the second portion of the data based on one or more metrics of the decoder, which may include a syndrome weight, bit-flip status, a column weight, a bit-position, block index, or the like. In aspects, the adaptive LDPC decoder selects or updates the parameters or thresholds for decoding a portion of the bits at least one time during a decoding iteration, such that the bits to be decoded are not decoded using only one bit-flipping threshold.

At 708, the LDPC decoder processes a second portion of the data using the second parameters. To process the second portion of the data, the adaptive LDPC decoder flips bits or symbols of the second portion of the bit nodes or the variable nodes based on the second parameters (e.g., bit-flip thresholds). The second parameters may include decoding rules or decoding thresholds by which the bits of the second portion of the data are processed. Processing the second portion of the data may also be effective to change the status of the decoder, including another update to the syndrome weight of the decoder, which may change or update each time a bit or symbol of the LDPC code is flipped from a current value to a different value. From operation 708, the method 700 may return to operation 706 to process another portion of data during an instant iteration or may proceed to operation 710 to determine whether the bits of data have been decoded. The operations 706 and 708 may be repeated iteratively until all portions of the data are processed to complete one decoding iteration.

At 710, the controller of the LDPC decoder determines whether the data is decoded. In some cases, the LDPC decoder computes a sum of the syndrome updates to determine if the syndrome weight of the decoder reaches zero, indicating successful decoding of the bits of data. If the syndrome weight of the LDPC decoder is not zero, the method 700 may return to operation 702 to feed the partially decoded bits back into the decoder for another decoding iteration. Alternatively, the LDPC decoder may compare an iteration index to a maximum iteration threshold, and if the maximum iteration threshold is exceeded, the LDPC decoder may cease decoding operations and provide the currently decoded bits as an output of the LDPC decoder at operation 712.

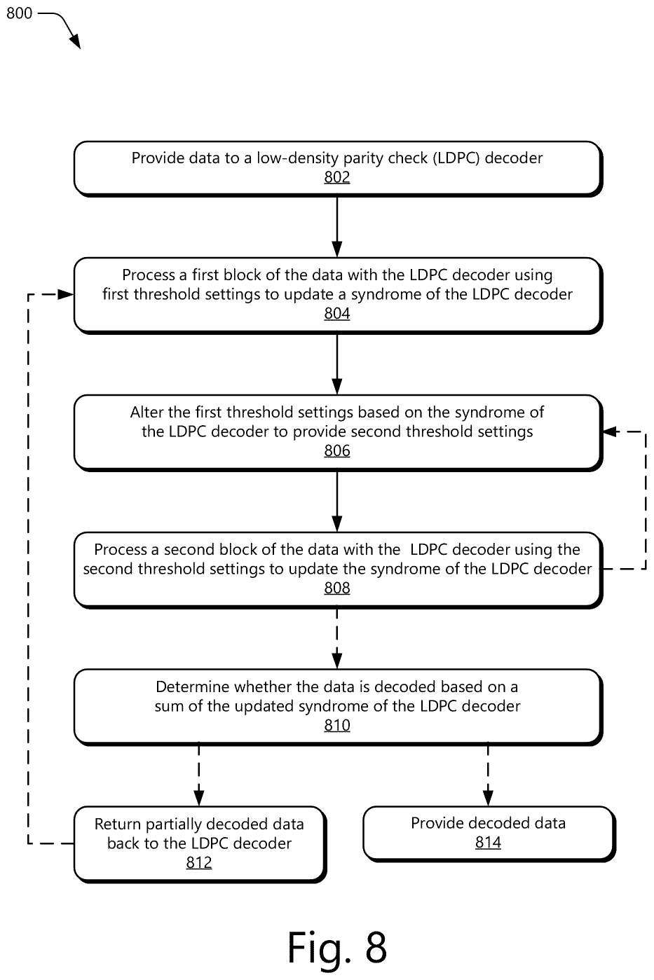

FIG. 8 depicts an example method 800 for implementing adaptive LDPC decoding based on a syndrome of a decoder, including operations performed by or with an LDPC decoder 130, decoding parameters 132, decoding metrics 134, or an adaptive controller 136 associated with the adaptive LDPC decoder.

At 802, data is provided to an LDPC decoder, which can be configured as an adaptive LDPC decoder or include an adaptive controller. The data may be received from a channel, such as a storage channel or a communication channel. Due to noise in the channel, one or more bits of the data (e.g., one or more bits of a data codeword) may be flipped or incorrect. Thus, the bits of the received data or read data may include flipped bits or bit errors in an ECC coding of the data. In aspects, the adaptive LDPC decoder divides or apportions the data of the graph or matrix into multiple blocks of bits or subsets of bits for processing during an iteration of decoding. For example, the adaptive LDPC decoder may divide the data into at least two portions of bits for decoding, and in some implementations may divide the data into three portions, four portions, or any suitable number of portions (e.g., based on received data quality (bit-error rate) and/or decoder complexity).

At 804, the LDPC decoder processes a first block of the data using first threshold settings to update a syndrome of the LDPC decoder. To process the first block of the data, the adaptive LDPC decoder flips bits or symbols of the first block of bit nodes or variable nodes based on the first threshold settings, such as those described with reference to FIG. 5 or FIG. 6. The LDPC decoder may select the first threshold settings for decoding the first block of the data based on one or more metrics of the decoder, which may include a syndrome weight, bit-flip status, column weight, a bit-position, block index, or the like. The syndrome or syndrome weight of the decoder may change or update each time a bit or symbol of the LDPC code is flipped from a current value to a different value.

At 806, an adaptive controller of the LDPC decoder alters the first threshold settings based on the syndrome of the LDPC decoder to provide second threshold settings. Additionally, the LDPC decoder may alter the first threshold settings based on another metric of the decoder or the data being decoded, which may include a column weight of the parity check matrix, a bit-position of a bit node or variable node, a bit-flip status, a block index, or the like. In aspects, the adaptive LDPC decoder access a table of threshold values to select the second threshold settings, such as described with reference to FIG. 5 or FIG. 6. Thus, the adaptive LDPC decoder may process or decode each of multiple portions of data bits using a respective set of decoding parameters that are dynamically selected based on the state of the LDPC decoder.

At 808, LDPC decoder processes a second block of the data using the second threshold settings to update the syndrome of the LDPC decoder. To process the second block of the data, the adaptive LDPC decoder flips bits or symbols of the second block of the bit nodes or the variable nodes based on the second threshold settings (e.g., bit-flip thresholds). Processing the bits of the second block of the data updates the syndrome of the decoder, which may change or update each time a bit or symbol of the LDPC code is flipped from a current value to a different value. From operation 808, the LDPC decoder may return to operation 806 to alter current threshold settings of the LDPC decoder based on the updated syndrome resulting from processing the second block of data or a subsequent block of data (e.g., on another block iteration) and process a next block of the data. The operations 806 and 808 may be repeated iteratively until all blocks or bit types of the data are processed to complete one decoding iteration. Alternatively, the LDPC decoder may advance to operation 810 at which a determination is made as to whether the data is decoded based on a sum of the updated syndrome of the LDPC decoder.

At 810, the LDPC decoder determines whether the data is decoded based on a sum of the updated syndrome of the decoder. In some cases, the LDPC decoder determines if the syndrome weight of the decoder reaches zero, indicating successful decoding of the bits of data. If the syndrome weight of the LDPC decoder is not zero, the method 800 may, at 812, return to operation 804 to feed the partially decoded bits back into the decoder for another decoding iteration. Alternatively, the LDPC decoder may compare an iteration index to a maximum iteration threshold, and if the maximum iteration threshold is exceeded, the LDPC decoder may cease decoding operations. When the data is successfully decoded or a maximum number of iterations is reached, the LDPC decoder may provide the decoded bits as an output of the decoder at operation 814.

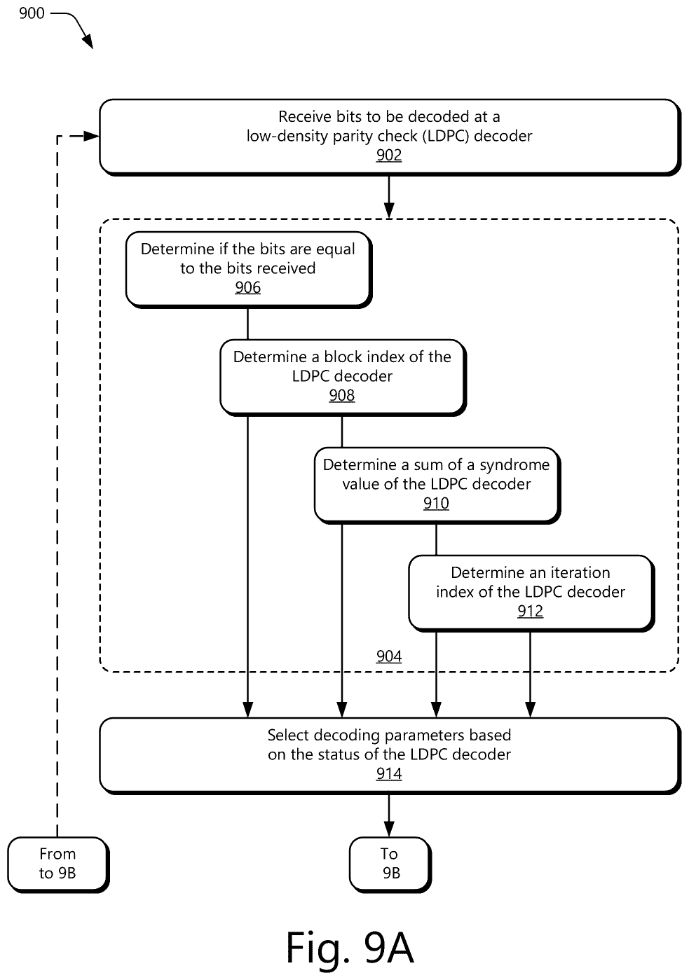

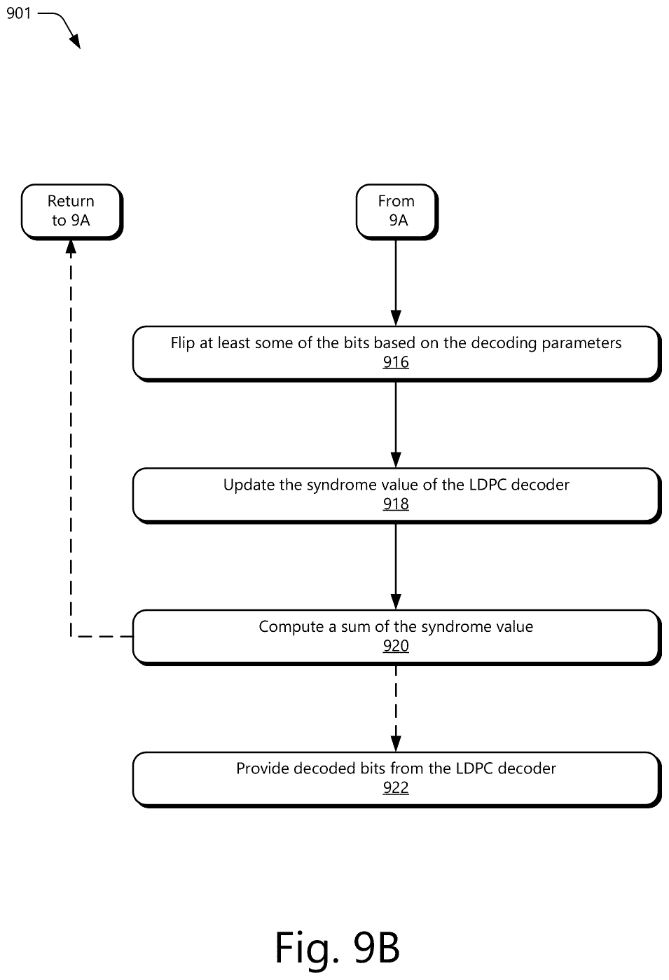

FIGS. 9A and 9B depict an example method 900 for selecting decoding parameters of an adaptive LDPC decoder based on a status of the decoder, including operations performed by or with an LDPC decoder 130, decoding parameters 132, decoding metrics 134, or an adaptive controller 136 associated with the adaptive LDPC decoder.

At 902, an LDPC decoder receives or is provided bits to be decoded. The data may be received from a channel, such as a storage channel or a communication channel. Due to noise in the channel, one or more bits of the data (e.g., one or more bits of a data codeword) may be flipped or incorrect. In aspects, the adaptive decoder may determine multiple portions or subsets of data from the received data, which may then be processed using decoding parameters adaptively selected or determined for each of the multiple portions or subsets of data (e.g., bits).

At 904, a status of the LDPC decoder is determined based on one or more metrics of the LDPC decoder. Generally, determining the status of the decoder may include determining state information of the decoder and/or metrics of the bit nodes or variable nodes of a data graph being decoded. As shown in FIG. 9A, the LDPC decoder can determine at 906 if the bits are equal in value to the bits received (e.g., bit-flip status), determine a block index of the LDPC decoder at 908, determine at 910 a sum of a syndrome value or vector of the LDPC decoder, or determine an iteration index of the LDPC decoder at 912.

At 914, an adaptive controller of the LDPC decoder selects decoding parameters based on the status of the LDPC decoder. For example, based on the status and/or metrics of the decoder, the adaptive controller can access a table of bit-flip threshold settings and select the bit-flip threshold settings that correspond to the current state or status of the decoder, such as described with reference to FIG. 5 or FIG. 6. From operation 914, the method proceeds to operation 916 as illustrated at 901 of FIG. 9B.

At 916, the LDPC decoder flips at least some of the bits based on the decoding parameters. Generally, the adaptive LDPC decoder flips bits of the current block of bits with a number of unsatisfied checks greater than the threshold and then updates the syndrome of the decoder at 918. Note that the syndrome of the decoder may change or update after each bit is flipped, and the decoder may track the syndrome update or syndrome weight on a per-bit-flip basis, which may enable dynamic adjustment of decoding rules or thresholds.

At 920, a sum of the syndrome is computed. In aspects, the adaptive LDPC decoder sums the syndrome update at the end of the decoding iteration and if the syndrome sum equals zero, the adaptive LDPC decoder provides the decoded data at 922 as a decoding success. Otherwise, the adaptive LDPC decoder returns to operation 902 to feed the current iteration of the decoded bits including the flipped bits back for another iteration of decoding by the adaptive LDPC decoder. The operations of method 900 may repeat until the syndrome sum reaches zero or the adaptive LDPC decoder encounters the maximum number of decoding iterations allowed.

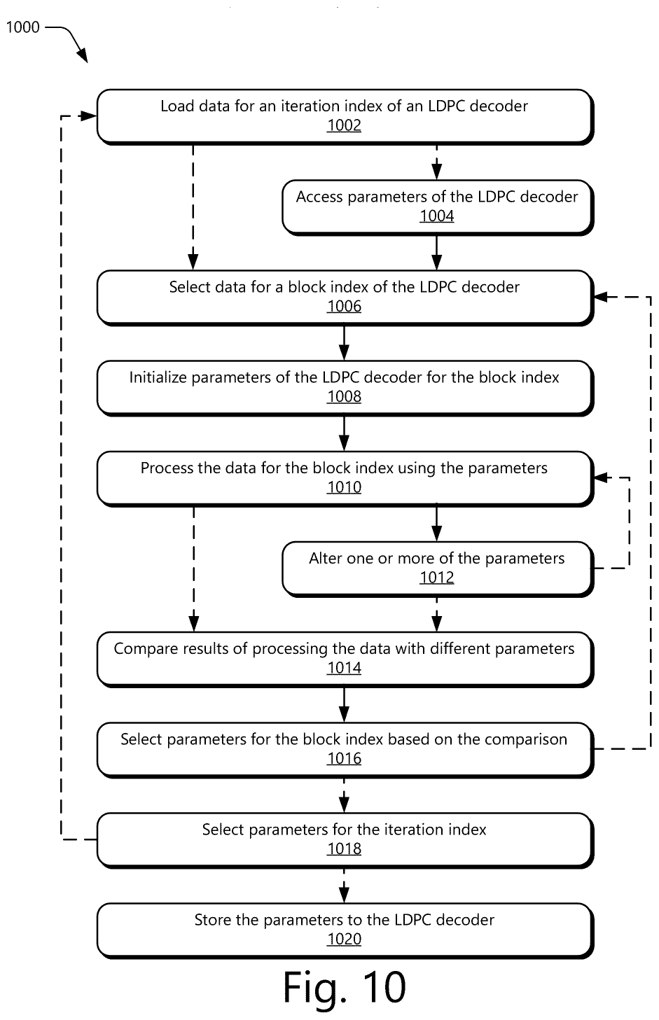

FIG. 10 depicts an example method 1000 for selecting parameters of an adaptive LDPC decoder based on results of processing data with combinations of parameters, including operations performed by or with an LDPC decoder 130, decoding parameters 132, decoding metrics 134, or an adaptive controller 136 associated with the adaptive LDPC decoder. In aspects, the method 1000 may be implemented as an optimization of threshold settings based on a “greedy search” in which a cost function in the optimization can be configured to maximize a number of corrected bits for each block of bit nodes decoded. For example, the method 1000 may be used to optimize the threshold tables described with reference to FIG. 6 for any suitable number of iteration indices and/or block indices.

At 1002, data is loaded for an iteration index of an LDPC decoder. The data may be training data, randomized data, or live data of an LDPC code obtained from a channel. Optionally at 1004, current parameters of the LDPC decoder are accessed, which may include previously optimized parameters or parameters currently configured as threshold settings for the decoder.

At 1006, data for a block index of the LDPC decoder is selected for decoding. In some implementations, the method 1000 is performed iteratively for m blocks by advancing through each block index of 1 to m−1. At 1008, parameters of the LDPC decoder are initialized for the block index of the currently selected data or bit nodes. This may include setting bit-flip thresholds for the data of the block index to be processed. At 1010, data of the block index is processed with the LDPC decoder using the parameters and performance of the decoder may be monitored during the processing. In some cases, the data is processed by running a performance simulation with currently optimized thresholds that were saved in a threshold table from all the previous iterations from 1 to i−1 and for the blocks 1 to m−1 in iteration i. At 1012, one or more of the decoding parameters are altered, such that the performance simulation may evaluate multiple combinations of decoding parameters or thresholds. In some cases, the performance simulation may concurrently run for all possible threshold combinations for a current block index m in the iteration i that is being evaluated or simulated.

At 1014, the results of processing the data for the block index with different parameters are compared and, at 1016, parameters are selected for the block index based on the comparison of results. For example, after processing the results generated from the performance simulation, optimal thresholds can be selected that yield a maximum number of corrected bits in this block. From operation 1016, the method can proceed to a next block and process the next block with different combinations of parameters, such as until all blocks in the iteration are exhausted. After all blocks of the iteration have been processed, the method may proceed to operation 1018 at which the parameters (e.g., optimal parameters or thresholds) are selected for this iteration index based on processing results of each block or the thresholds selected for the block indices based on the decoding results.

From operation 1018, after the parameters are selected for the iteration index, the method may return to operation 1002 to load data for another iteration index of the LDPC decoder and iteratively process the data for that index on a block-by-block basis to determine parameters for another iteration index of the decoder. Thus, the operations of the method 1000 may be performed iteratively to process multiple blocks of each iteration index, which may provide optimal decoding thresholds for multiple iteration indices. After decoding parameters or thresholds have been determined for one or more iteration indices of the LDPC decoder, the method 1000 may advance to operation 1020 to store the parameters to the LDPC decoder. In aspects, the LDPC decoder or adaptive controller stores optimal decoding parameters or thresholds to a table based on an iteration number index, block index, and syndrome weight range, such as to provide tables similar to those described herein.

System-On-Chip and Controller

FIG. 11 illustrates an example System-on-Chip (SoC) 1100 environment in which various aspects of adaptive LDPC decoding may be implemented. The SoC 1100 may be implemented in any suitable system or device, such as a smart-phone, a netbook, a tablet computer, an access point, a network-attached storage device, a camera, a smart appliance, a printer, a set-top box, a server, a data storage center, a solid-state drive (SSD), a hard disk drive (HDD), an optical storage drive, a holographic storage system, a storage drive array, a memory module, an automotive computing system, or an aggregate storage controller, or any other suitable type of device (e.g., others described herein). Although described with reference to an SoC, the entities of FIG. 11 may also be implemented as other types of integrated circuits or embedded systems, such as an application-specific integrated-circuit (ASIC), memory controller, storage controller, communication controller, application-specific standard product (ASSP), digital signal processor (DSP), programmable SoC (PSoC), system-in-package (SiP), or field-programmable gate array (FPGA).

The SoC 1100 may be integrated with electronic circuitry, a microprocessor, memory, input-output (I/O) control logic, communication interfaces, firmware, and/or software useful to provide functionalities of a computing device, host system, or storage system, such as any of the devices or components described herein (e.g., storage drive or storage array). The SoC 1100 may also include an integrated data bus or interconnect fabric (not shown) that couples the various components of the SoC for control signaling, data communication, and/or routing between the components. The integrated data bus, interconnect fabric, or other components of the SoC 1100 may be exposed or accessed through an external port, a parallel data interface, a serial data interface, a fabric-based interface, a peripheral component interface, or any other suitable data interface. For example, the components of the SoC 1100 may access or control external storage media, processing blocks, neural networks, datasets, or AI models, through an external interface or off-chip data interface.

In this example, the SoC 1100 includes various components such as input-output (I/O) control logic 1102 and a hardware-based processor 1104 (processor 1104), such as a microprocessor, a processor core, an application processor, DSP, or the like. The SoC 1100 also includes memory 1106, which may include any type and/or combination of RAM, SRAM, DRAM, non-volatile memory, ROM, one-time programmable (OTP) memory, multiple-time programmable (MTP) memory, Flash memory, and/or other suitable electronic data storage. In some aspects, the processor 1104 and code stored on the memory 1106 are implemented as a storage system controller or storage aggregator to provide various functionalities associated with adaptive LDPC decoding. In the context of this disclosure, the memory 1106 stores data, code, instructions, or other information via non-transitory signals, and does not include carrier waves or transitory signals. Alternately or additionally, the SoC 1100 may comprise a data interface (not shown) for accessing additional or expandable off-chip storage media, such as solid-state memory (e.g., Flash or NAND memory), magnetic-based memory media, or optical-based memory media.

The SoC 1100 may also include firmware 1108, applications, programs, software, and/or an operating system, which may be embodied as processor-executable instructions maintained on the memory 1106 for execution by the processor 1104 to implement functionalities of the SoC 1100. The SoC 1100 may also include other communication interfaces, such as a transceiver interface for controlling or communicating with components of a local on-chip (not shown) or off-chip communication transceiver. Thus, in some aspects, the SoC 1100 may be implemented or configured as a communications transceiver that is capable of implementing aspects of adaptive LDPC decoding to process data received through a communication channel. Alternately or additionally, the transceiver interface may also include or implement a signal interface to communicate radio frequency (RF), intermediate frequency (IF), or baseband frequency signals off-chip to facilitate wired or wireless communication through transceivers, physical layer transceivers (PHYs), or media access controllers (MACs) coupled to the SoC 1100. For example, the SoC 1100 may include a transceiver interface configured to enable storage over a wired or wireless network, such as to provide a network attached storage (NAS) volume with adaptive LDPC decoding for communicated data and/or stored data.

The SoC 1100 also includes an LDPC decoder 130, processing block 214, and adaptive controller 136, which may be implemented separately as shown or combined with a storage component, host controller, data interface, data transceiver. In accordance with various aspects of adaptive LDPC decoding, the LDPC decoder 130 and adaptive controller 136 process a first portion of data (e.g., a block of data) of a channel using first parameters effective to change a status (e.g., a syndrome weight) of the decoder and selects second parameters based on the status of the decoder. The LDPC decoder 130 is then configured with the second parameters and processes a second portion of the data (e.g., another block of data) using the second parameters, which may further update the status of the LDPC decoder. The LDPC decoder 130 provides decoded data of the channel based on least the processing of the first portion of data using the first parameters and the processing of the second portion of the data using the second parameters. Any of these entities may be embodied as disparate or combined components, as described with reference to various aspects presented herein. For example, the adaptive controller may be implemented as part of the LDPC decoder 130 or processing block 214 of a storage controller or communication transceiver. Examples of these components and/or entities, or of corresponding functionality, are described with reference to the respective components or entities of the environment 100 of FIG. 1 or the respective configurations illustrated in FIG. 2 through FIG. 6, and/or the methods 700 through 1000 of FIG. 7 through FIG. 10. The LDPC decoder 130 or adaptive controller 136, either in whole or in part, may be implemented as processor-executable instructions maintained by the memory 1106 and executed by the processor 1104 to implement various aspects and/or features of adaptive LDPC decoding.

The adaptive LDPC decoder 130 and/or processing block 214, may be implemented independently or in combination with any suitable component or circuitry to implement aspects described herein. For example, the adaptive LDPC decoder 130 or processing block 214 may be implemented as part of a DSP, processor/storage bridge, I/O bridge, graphics processing unit, memory controller, storage controller, arithmetic logic unit (ALU), or the like. The adaptive LDPC decoder 130 may also be provided integrally with other entities of the SoC 1100, such as integrated with the processor 1104, the memory 1106, a storage media interface, or the firmware 1108 of the SoC 1100. Alternately or additionally, the adaptive LDPC decoder 130, processing block 214, and/or other components of the SoC 1100 may be implemented as hardware, firmware, fixed logic circuitry, or any combination thereof.

As another example, consider FIG. 12 which illustrates an example storage system controller 1200 in accordance with one or more aspects of adaptive LDPC decoding. In various aspects, the storage system controller 1200 or any combination of components thereof may be implemented as a storage drive controller, distributed storage center controller (e.g., among a host and SSDs), storage media controller, NAS controller, Fabric interface, NVMe target, or storage aggregation controller for storage media. In some cases, the storage system controller 1200 is implemented similarly to or with components of the SoC 1100 as described with reference to FIG. 11. In other words, an instance of the SoC 1100 may be configured as a storage system controller, such as the storage system controller 1200 to manage storage media (e.g., NAND Flash-based or magnetic media) with aspects of adaptive LDPC decoding.

As shown in FIG. 12, the storage system controller 1200 includes input-output (I/O) control logic 1202 and a processor 1204, such as a microprocessor, a processor core, an application processor, a DSP, or the like. In some aspects, the processor 1204 and firmware of the storage system controller 1200 may be implemented to provide various functionalities associated with adaptive LDPC decoding, such as those described with reference to any of the methods 700 through 1000. The storage system controller 1200 also includes a host interface 1206 (e.g., SATA, PCIe, NVMe, or Fabric interface) and a storage media interface 1208 (e.g., NAND interface, read/write channel), which enable access to a host system and storage media, respectively. The storage system controller 1200 may also include a Flash translation layer 1210 (FTL 1210), SRAM (not shown), and/or a DRAM controller (not shown). In some aspects of adaptive LDPC decoding, the FTL 1210 interacts with an LDPC decoder 130 and/or an adaptive controller 136 to decode data read from storage media that is operably coupled with the storage media interface 1208.

In this example, the storage system controller 1200 also includes instances of processing block 214, LDPC decoder 130, decoding parameters 132, decoding metrics 134, and adaptive controller 136. Any or all of these components may be implemented separately as shown or combined with the processor 1204, the host interface 1206, the storage media interface 1208, the Flash translation layer 1210, and/or as an adaptive LDPC decoder of the storage system controller 1200. Examples of these components and/or entities, or of corresponding functionality, are described with reference to the respective components or entities of the environment 100 of FIG. 1 or the respective configurations illustrated in FIG. 2 through FIG. 6. In accordance with various aspects of adaptive LDPC decoding, the LDPC decoder 130 and adaptive controller 136 process a first portion of data (e.g., a block of data) of a channel using first parameters effective to change a status (e.g., a syndrome weight) of the decoder and selects second parameters based on the status of the decoder. The LDPC decoder 130 is then configured with the second parameters and processes a second portion of the data (e.g., another block of data) using the second parameters, which may further update the status of the LDPC decoder. The LDPC decoder 130 provides decoded data of the channel based on least the processing of the first portion of data using the first parameters and the processing of the second portion of the data using the second parameters. By adaptively selecting or changing the decoding parameters (e.g., bit-flipping or symbol-flipping thresholds) based on decoder status, the adaptive LDPC decoder 130 may decode channel data in fewer decoding iterations or with a higher success rate, thereby improving LDPC decoding performance.

In the following, some examples of adaptive LDPC decoding are described in accordance with one or more aspects:
Example 1: A method for adaptive low-density parity check decoding, comprising: processing a first portion of data of a channel with a low-density parity check (LDPC) decoder using first parameters effective to change a status of the LDPC decoder; selecting second parameters of the LDPC decoder based on the status of the LDPC decoder; processing a second portion of the data with the LDPC decoder using the second parameters; and providing decoded data of the channel based on at least the processing the first portion of the data with the first parameters and the processing of the second portion of the data with the second parameters.
Example 2: The method of any of the examples, further comprising receiving the data from the channel and providing the data of the channel to the LDPC decoder.
Example 3: The method of any of the examples, wherein the receiving the data of the channel comprises: receiving the data from a storage channel via a storage media interface; or receiving the data from a communication channel via a transceiver.
Example 4: The method of any of the examples, further comprising: selecting third parameters of the LDPC decoder based on the status of the LDPC decoder after processing at least part of the second portion of the data; processing a third portion of the data with the LDPC decoder using the third parameters; and providing decoded data of the channel based on at least the processing the first portion of the data with the first parameters, the processing of the second portion of the data with the second parameters, and the processing of the third portion of the data with the third parameters.
Example 5: The method of any of the examples, wherein the status of the LDPC decoder comprises one of: a syndrome weight of the LDPC decoder; a column weight of the parity check matrix; a bit-position of a bit of the data; an LDPC code implemented by the LDPC decoder to decode the data; a degree of one or more bits of the data; a block index of the LDPC decoder; or an iteration index of the LDPC decoder.
Example 6: The method of any of the examples, wherein the first parameters or the second parameters comprise one of: an LDPC decoding rule; a value of an LDPC decision threshold; a bit-flipping threshold for a bit that has been flipped; a bit-flipping threshold for a bit that has not been flipped; a symbol-flipping threshold for a symbol that has been flipped; or a symbol-flipping threshold for a symbol that has not been flipped.
Example 7: The method of any of the examples, wherein: the processing of the first portion of the data with the LDPC decoder comprises flipping a bit value of a variable node representative of a corresponding bit in the first portion of the data; or the processing of the second portion of the data with the LDPC decoder comprises flipping a bit value of a variable node representative of a corresponding bit in the second portion of the data.
Example 8: The method of any of the examples, wherein: the first portion of the data corresponds to a first block of the data; the second portion of the data corresponds to second block of the data; and the method further comprises determining, from the data, multiple blocks of the data that include at least the first block of data and the second block of data, wherein the status of the decoder based on which the second parameters are selected includes an index of the second block of the data.
Example 9: The method of any of the examples, wherein: each of the multiple blocks of the data comprises a type of bit-node that corresponds to a degree of bit-node in a parity check matrix of the LDPC decoder; and the determining of the multiple blocks comprises forming each of the multiple blocks with one bit-node type of the data from at least two types of bit-nodes defined for the LDPC decoder.
Example 10: The method of any of the examples, wherein: the first portion of the data and the second portion of the data are processed during a single iteration of the LDPC decoder; and the status of the LDPC decoder comprises an intermediate status of the LDPC decoder obtained during the single iteration of the processing of the data of the channel.
Example 11: The method of any of the examples, wherein: the data comprises data read from storage media; and the storage media comprises one of optical storage media, magnetic storage media, holographic storage media, solid-state storage media, NAND Flash memory, single-level cell (SLC) Flash memory, multi-level cell (MLC) Flash memory, triple-level cell (TLC) Flash, quad-level cell Flash (QLC), or NOR cell Flash.
Example 12: An apparatus comprising: a data interface configured for communication of data through a channel; a low-density parity check (LDPC) decoder; and an adaptive controller for the LDPC decoder, the adaptive controller configured to implement any method of the examples.
Example 13: A System-on-Chip (SoC) comprising: a media interface to access storage media of a storage media system; a host interface to communicate with a host system; a low-density parity check (LDPC) decoder; and an adaptive controller for the LDPC decoder configured to implement any method of the examples.

Although the subject matter of an adaptive LDPC decoder has been described in language specific to structural features and/or methodological operations, it is to be understood that the subject matter defined in the appended claims is not necessarily limited to the specific examples, features, or operations described herein, including orders in which they are performed.

What is claimed is:

1. A method for adaptive low-density parity check decoding, comprising:
processing a first portion of data of a channel with a low-density parity check (LDPC) decoder using first parameters effective to change a status of the LDPC decoder;
selecting second parameters of the LDPC decoder based on the status of the LDPC decoder;
processing a second portion of the data with the LDPC decoder using the second parameters; and
providing decoded data of the channel based on at least the processing the first portion of the data with the first parameters and the processing of the second portion of the data with the second parameters.

2. The method of claim 1, further comprising receiving the data from the channel and providing the data of the channel to the LDPC decoder.

3. The method of claim 2, wherein the receiving the data of the channel comprises:
receiving the data from a storage channel via a storage media interface; or
receiving the data from a communication channel via a transceiver.

4. The method of claim 1, wherein the status of the LDPC decoder comprises one of:
a syndrome weight of the LDPC decoder;
a column weight of the parity check matrix;
a bit-position of a bit of the data;
an LDPC code implemented by the LDPC decoder to decode the data;
a degree of one or more bits of the data;
a block index of the LDPC decoder; or
an iteration index of the LDPC decoder.

5. The method of claim 1, wherein the first parameters or the second parameters comprise one of:
an LDPC decoding rule;
a value of an LDPC decision threshold;
a bit-flipping threshold for a bit that has been flipped;
a bit-flipping threshold for a bit that has not been flipped;
a symbol-flipping threshold for a symbol that has been flipped; or
a symbol-flipping threshold for a symbol that has not been flipped.

6. The method of claim 1, wherein:
the processing of the first portion of the data with the LDPC decoder comprises flipping a bit value of a variable node representative of a corresponding bit in the first portion of the data; or
the processing of the second portion of the data with the LDPC decoder comprises flipping a bit value of a variable node representative of a corresponding bit in the second portion of the data.

7. The method of claim 6, wherein:
the first portion of the data corresponds to a first block of the data;
the second portion of the data corresponds to second block of the data; and
the method further comprises determining, from the data, multiple blocks of the data that include at least the first block of data and the second block of data,
wherein the status of the decoder based on which the second parameters are selected includes an index of the second block of the data.

8. The method of claim 7, wherein:
each of the multiple blocks of the data comprises a type of bit-node that corresponds to a degree of bit-node in a parity check matrix of the LDPC decoder; and
the determining of the multiple blocks comprises forming each of the multiple blocks with one bit-node type of the data from at least two types of bit-nodes defined for the LDPC decoder.

9. The method of claim 1, wherein:
the first portion of the data and the second portion of the data are processed during a single iteration of the LDPC decoder; and
the status of the LDPC decoder comprises an intermediate status of the LDPC decoder obtained during the single iteration of the processing of the data of the channel.

10. The method of claim 1, wherein:
the data comprises data read from storage media; and
the storage media comprises one of optical storage media, magnetic storage media, holographic storage media, solid-state storage media, NAND Flash memory, single-level cell (SLC) Flash memory, multi-level cell (MLC) Flash memory, triple-level cell (TLC) Flash, quad-level cell Flash (QLC), or NOR cell Flash.

11. An apparatus comprising:
a data interface configured for communication of data through a channel;
a low-density parity check (LDPC) decoder; and
an adaptive controller for the LDPC decoder, the adaptive controller configured to:
process, with the LDPC decoder and using first parameters, a first block of data received from the channel effective to change metrics of the LDPC decoder;
select second parameters for the LDPC decoder based on the metrics of the LDPC decoder;
process, with the LDPC decoder and using the second parameters, a second block of the data; and
provide decoded data of the channel based on at least the processing of the first block using the first parameters and the processing of the second block using the second parameters.

12. The apparatus of claim 11, wherein:
the data interface comprises a storage media interface and the apparatus is further configured to read, via the storage media interface, the data from storage media operably coupled to the apparatus; or
the data interface comprises a data transceiver and the apparatus is further configured to receive, via the data transceiver, the data through the channel from a transmitter.

13. The apparatus of claim 11, wherein:
the metrics of the LDPC decoder are intermediate metrics of an iteration of decoding the data from the channel; and
the metrics of the LDPC decoder comprise one or more of:
a syndrome weight of the LDPC decoder;
a column weight of the parity check matrix;
a bit-position of a bit of the data;
an LDPC code implemented by the LDPC decoder to decode the data;
a degree of one or more bits of the data;
a block index of the LDPC decoder; or
an iteration index of the LDPC decoder.

14. The apparatus of claim 11, wherein the first parameters or the second parameters of the LDPC decoder comprise one of:
an LDPC decoding rule;
a value of an LDPC decision threshold;
a bit-flipping threshold for a bit that has been flipped;
a bit-flipping threshold for a bit that has not been flipped;
a symbol-flipping threshold for a symbol that has been flipped; or
a symbol-flipping threshold for a symbol that has not been flipped.

15. The apparatus of claim 14, wherein:
the adaptive controller is further configured to determine, from the data, multiple blocks of the data that include at least the first block of data and the second block of data; and
wherein the metrics of the decoder based on which the second parameters are selected includes an index of the second block of the data.

16. A System-on-Chip (SoC) comprising:
a media interface to access storage media of a storage media system;
a host interface to communicate with a host system;
a low-density parity check (LDPC) decoder; and
an adaptive controller for the LDPC decoder configured to:
process, with the LDPC decoder and using first parameters, a first block of data received from the storage media system effective to change a status of the LDPC decoder;
select second parameters for the LDPC decoder based on the status of the LDPC decoder;
process, with the LDPC decoder and using the second parameters, a second block of the data; and
provide decoded data of the storage media system based on at least the processing of the first block of data using the first parameters and the processing of the second block of data using the second parameters.

17. The SoC of claim 16, wherein the status of the LDPC decoder comprises one of:
a syndrome weight of the LDPC decoder;
a syndrome weight of the LDPC decoder;
a bit-position of a bit of the data;
an LDPC code implemented by the LDPC decoder to decode the data;
a degree of one or more bits of the data;
a block index of the LDPC decoder; or
an iteration index of the LDPC decoder.

18. The SoC of claim 16, wherein the first parameters or the second parameters comprise one of:
an LDPC decoding rule;
a value of an LDPC decision threshold;
a bit-flipping threshold for a bit that has been flipped;
a bit-flipping threshold for a bit that has not been flipped;
a symbol-flipping threshold for a symbol that has been flipped; or
a symbol-flipping threshold for a symbol that has not been flipped.

19. The SoC of claim 16, wherein:
the adaptive controller is further configured to determine, from the data, multiple blocks of the data that include at least the first block of data and the second block of data; and
wherein the status of the decoder based on which the second parameters are selected includes an index of the second block of the data.

20. The SoC of claim 19, wherein:
each of the multiple blocks of the data comprises a type of bit-node that corresponds to a degree of bit-node in a parity check matrix of the LDPC decoder; and
to determine the multiple blocks, the adaptive controller is configured to form each of the multiple blocks with one bit-node type of the data from at least two types of bit-nodes defined for the LDPC decoder.
